(19) United States
(12) Patent Application Publication
(10) Pub. No.: US 2010/0096168 A1
(43) Pub. Date: Apr. 22, 2010

(54) ELECTRIC CONTACT AND METHOD FOR PRODUCING THE SAME AND CONNECTOR USING THE ELECTRIC CONTACTS

(76) Inventors: Tomonari Ohtsuki, Tokyo (JP); Yasue Yamazaki, Tokyo (JP); Hirofumi Daimon, Tokyo (JP); Kozo Matsuo, Noda-shi (JP); Sachi Takami, Noda-shi (JP)

Correspondence Address: ABELMAN, FRAYNE & SCHWAB, 666 THIRD AVENUE, 10TH FLOOR, NEW YORK, NY, 10017, US

(21) Appl. No.: 12/626,293

(22) Filed: Nov. 25, 2009

Related U.S. Application Data
(63) Continuation of application No. 11/527,852, filed on Sep. 26, 2006, now abandoned.

(30) Foreign Application Priority Data
Sep. 26, 2005 (JP) 2005-277,320
Nov. 30, 2005 (JP) 2005-344,971

(51) Int. Cl. H05K 1/00

(52) U.S. Cl. 174/254; 174/261

(57) ABSTRACT

A board consisting of a polyimide layer and copper foils is worked from one direction by etching to form through-holes, and the copper foils and inside of the through-holes are plated with copper, or the board is worked by etching or laser machining to form blind holes to expose the copper foils on the other side and through-holes simultaneously, and copper foils and insides of the blind holes and the through-holes are plated with copper. A metal ball plated with a noble metal is fixed on the copper foil by solidification of a metal paste to form an electric contact. Two superimposed plastic sheets are formed with holes each having a projection on inner wall of the hole, thereby vertically holding conductors by the projections of the holes of the superimposed plastic sheets. A laser beam machining method fabricates grooves or slits in a workpiece.

### BACKGROUND OF THE INVENTION

This invention relates to a method for producing a flexible printed circuit board formed with a plurality of through-holes, and more particularly to electric contacts and methods for producing the electric contacts whose heights are uniform and as high as possible without increasing their diameters, and further to electric contacts each having a shape adapted to that of a mating object, or having a wear resistant conductive hard film on a portion adapted to contact a mating object, or each comprising copper foils on both sides of a board and adapted to be electrically connected to each other. The invention further relates to a structure for vertically holding conductors in the form of a pin, a method for producing plastic sheets for use in the structure, and a laser beam machining method for forming slits having a width less than and a length larger than a focused laser beam diameter, and more particularly to connectors using the structure and utilizing the methods for their production.

In order to achieve electrical continuity across upper and lower surfaces of a flexible printed circuit board, there have been through-holes as disclosed in descriptions concerning the prior art and problems to be solved in

Patent Literature 1, Japanese Patent Application Opened No. H6-164,084 (1994) later described, and blind holes as disclosed in the abstract, claims and embodiments in the Patent Literature 1.

In bringing electronic components into contact with a circuit board, there have in the past been various cases that one is flat and the other is frequently extended (for example, substantially in the form of a hemisphere), and one is extended and the other is flat as the case may be.

The applicant of the present application has proposed an electric contact in Patent Literature 2 (Japanese Patent Application Opened No. 2004-335,666) later described. On proceeding of narrower pitches of electric contacts, however, when contacts having a certain height are formed, the diameter of the contacts becomes larger in comparison with the narrow pitch so that the contacts are arranged in close proximity to one another, thereby resulting into defective or failed electrical connection and causing short circuit. Even if the contacts are spaced apart as much as possible to avoid such problems, it will be attended with a reduced overall height of the contacts, which is far below the predetermined height. In order to overcome such problems, therefore, the applicant of the present application has proposed a contact as disclosed in Patent Literature 3 (Japanese Patent Application No. 2005-277,320) later described.

In the prior art, moreover, there have been provided on either or both of the surfaces of a flexible printed circuit board with the contacts such as disclosed in the Patent Literatures 2 and 3 as shown in FIGS. 14A and 14B attached to the present application.

In order to hold conductors in the form of a pin vertically in the past, such conductors have been inserted into holes of an object, which are formed as perpendicular as possible to both surfaces of the object by drilling or laser beam machining. There is no patent literature to be incorporated herein within the scope of our research for such structures for vertically holding conductors.

The applicant of the present application has proposed a connector comprising a circuit board formed with U-shaped slits about contact portions (electric contact elements) to cause sliding movement between the contact portions and mating contacts when they contact each other, and an elastomer provided under the contact portions as disclosed in Patent Literature 4 (Japanese

Patent Application Opened No. 2000-67,972) later described. Moreover, the applicant of the present application has proposed a laser beam machining method as disclosed in Patent Literature 5 (Japanese Patent Application Opened No. 2005-342,738) later described.

Patent Literature 1

According to the abstract of the Japanese Patent Application Opened No. H6-164,084 (1994), the invention has an object to form holes with high accuracy in a polyimide resin film with copper foils laminated on both the surface of the polyimide film. The polyimide layer of the polyimide films with the copper foils laminated on both the surfaces of the polyimide films consists of a plurality of polyimide films different in rate of being etched. In the case that the number of the laminated polyimide layers is three or more, polyimide layers being etched at a lower rate are arranged outside of the polyimide layer being etched at a faster rate. Etching is started from the polyimide layers being etched at the lower rate with an alkali solution or hydrazine, thereby forming holes without causing any side etching.

In connection with the above description, claim 1 of the Patent Literature 1 recites that in a polyimide circuit board consisting of a polyimide layer and conductive layers laminated on both surfaces of the polyimide layer, said polyimide layer consists of a plurality of layers different in etching characteristics. Claim 2 recites the polyimide circuit board as set forth in claim 1, wherein said polyimide layer comprises three or more polyimide layers arranged in a manner that the polyimide layers being etched at lower rates are arranged nearer to a surface on which an etching liquid acts than the polyimide layer being etched at a faster rate is arranged. Claim 3 recites an etching method for a polyimide circuit board of laminated polyimide and conductive layers, wherein the circuit board including laminated polyimide layers different in etching characteristics is etched by causing an etching liquid to act starting from the surface being etched at a lower rate. Claim 4 recites the etching method as set forth in claim 3 wherein said circuit board comprises a polyimide layer including three or more polyimide layers arranged in a manner that the polyimide layers being etched at lower rates are arranged nearer to the surface on which an etching liquid acts than the polyimide layer being etched at a lower rate is arranged.

Patent Literature 2

According to the abstract of the Japanese Patent Application No. 2004-335,666, following a step of filling a blind hole with a metal in a manner that the conductor itself in the blind hole becomes a contact of a connector, with a view to separating out the metal so as to increase the volume of the conductor in the blind hole to form a hemispherical shape, the inside of the blind hole is plated at first at a low current density, for example, of 0.5 to 10 A/dm², and after the plate layer arrive at the upper surface of the blind hole, the current density is adjusted and while keeping a current density of five to ten times the initial current density value, the metal is separated out so that the conductor in the blind hole becomes hemispherical whose dimensional ratio of radius to height approximates to substantially 1:1.

Patent Literature 3

According to the abstract of the Japanese Patent Application No. 2005-277,320, the invention has an object to provide electric contacts and a method for producing the electric contacts having a predetermined height without causing defective connection between the electric contacts. Disclosed is an electric contact extending from a copper foil in which the copper foil is coated with a metal paste layer, and a metal ball is fixed to the copper foil by solidification of the metal paste layer and is plated with gold over at least part adapted to contact a mating object. Further, disclosed is a method for producing an electric contact including steps of coating a copper foil with a metal paste layer over a predetermined area as a first step, arranging a metal ball on the metal paste layer and thereafter pushing the metal ball against the copper foil as a second step, solidifying the metal paste layer at a predetermined temperature to fix the metal ball to the copper foil as third step, and plating the metal ball with gold over at least part adapted to contact a mating object as a fourth step.

Patent Literature 4

According to abstract of the Japanese Patent Application Opened No. 2000-67,972, the invention has an object to provide an electrical connector capable of electrically connecting a plurality of electric contacts and a plurality of electric contact elements at a time. Disclosed is an electrical connector including a first connector plate portion and a second connector plate portion so that these first and second connector plate portions are detachably brought into abutment with each other to electrically connect a plurality of electric contacts on one surface of the first connector plate portion and a plurality of electric contact elements on one surface of the second connector plate portion to each other, respectively, wherein the electric contact elements are provided on a substrate of the second connector plate portion, while the substrate is formed with slits about the electric contact elements to provide elasticity them, thereby enabling the entire connector to be compact with a simple construction, preventing any failed connection due to non-uniform heights of the electric contacts, and readily ensuring desired impedance characteristics.

Patent Literature 5

According to the abstract of the Japanese Patent Application Opened No. 2005-342,738, the invention has an object to provide a laser beam machining method capable of perforating a plate to form perforations or holes less than 20 μm and cutting using inexpensive laser beam and capable of readily removing carbon particles adhering in machining and to provide stocks to be machined by the method. Disclosed is a method for perforating or cutting by laser beam, comprising steps of attaching a laser beam transparent film to a workpiece on the incident side of laser beam, machining the workpiece together with the film in that state by laser beam, peeling the laser beam transparent film, and attaching a sheet onto the workpiece on the opposite side from the incident side of laser beam.

In forming a through-hole in the past, as described in the Patent Literature 1 a flexible printed circuit board is worked from both the sides to cause holes (or grooves)on both the sides to communicate with each other to form a through-hole. The holes worked from the opposite sides are difficult to be accurately aligned with each other so that they tend to be staggered. Consequently, it is difficult to obtain a concentric through-hole with high positional accuracy using this prior art method. In more detail, in the laser beam machining used for machining a flexible printed circuit board from its both sides, respective holes are separately machined or a few holes are machined at a time. Therefore, this method is not suitable for machining a great many through-holes and tends to increase the manufacturing cost. In this way, it is difficult to obtain through-holes each consisting of accurately aligned halves, and through-holes with high positional accuracy. In order to improve the positional accuracy without increasing manufacturing cost, it has been proposed to perform working from one side of a board as in the Patent Literature 1 and to stop the working in the state of a blind hole when continuity across both surfaces occurs. However, there have been increasing demands of customers for inserting conductors into through-holes of perfect circle cross-section with high positional accuracy for electrical connection.

Recently, on proceeding of miniaturization of electric and electronic appliances, electrical connectors have been miniaturized and have been arranged with narrower pitches. In producing electric contacts on copper foils, on the other hand, the ratio of radius to height of hemispherical electric contacts is usually approximately 1:1 as disclosed in the Patent Literature 2.

On proceeding of narrower pitches of electric contacts in recent years, however, when contacts of a certain height are formed, the diameter of the electric contacts becomes larger in comparison with the narrow pitch so that the electric contacts are in close proximity to one another, thereby causing defective or failed electrical connection and short circuit as described above. Even if the contacts are spaced apart from one another as much as possible to avoid such problems, the height of the contacts must necessarily be lowered so that even required predetermined height cannot be ensured.

With an electrical connector having electric contacts arranged and equally spaced from one another, moreover, if the electric contacts are formed by plating, irregularities in diameter and height of the electric contacts will occur during plating depending upon positions in which they are arranged. Such problems remain to be solved.

In addition to the progress of the miniaturization of electrical connectors and narrower pitches of conductors following the miniaturization of electric and electronic appliances in recent years as described above, there has been increasing requirement for the electric contacts to be optimized so as to adapt to shapes of mating objects, respectively.

With the electric contacts each arranged on a copper foil of the flexible printed circuit board as disclosed in the Patent Literatures 2 and 3, on the other hand, there is a problem that a large amount of electric current could not be employed due to the thin copper foils. If thick copper foils are used, a large amount of current could be employed, but it would provide an impediment to the flexibility of the circuit board.

Moreover, when an electric contact as disclosed in the Patent Literature 2 or 3 is arranged on a copper foil of a flexible printed circuit board, as adherence between the copper plate layer and the cover lay is poor, a particular treatment for the cover lay will be needed, which is tedious and time-consuming, resulting in increased manufacturing cost.

With the construction disclosed in the Patent Literature 4, upon fitting (contacting) of the first and second connector plate portions, the contact portions of the former would slidably move on the contact portions of the latter. Owing to such a sliding movement, wear-resistance of the contact portions is required for repeated uses, and hence wet lubrication (wet wax) is applied to facilitate the sliding movement. However, the wet lubrication is likely to cause dust or dirt accumulation, resulting in defective or failed connection, and is gradually being dried over time to become poor in lubricating ability.

In order to overcome these problems, it is envisioned to use dry lubrication (application of diamond-like carbon coating) instead of the wet lubrication (wet wax). However, the dry lubrication (diamond-like carbon coating) is poor in conductivity, although superior in wear-resistance.

Insofar as the first and second connector plates are brought into contact with each other, it is required to achieve continuity between the contact portions and to be wear-resistant owing to their sliding movement upon contacting.

As described above, the miniaturization of the connectors and narrower pitches of conductors have been developed on proceeding of the miniaturization of the electric and electronic appliances in recent years. Accordingly, the parts (conductors and the like) to be used in appliances and connectors have been miniaturized, and further holes for holding conductors have become smaller.

If such holes could not be formed perpendicularly to surfaces of a plate to be formed with the holes, insertion of the conductors into the holes becomes difficult and hence vertically holding the conductors becomes impossible, resulting in defective or failed connection and obstruction of miniaturization of the appliances and connectors.

A number of holes are required for holding a number of conductors. However, the laser beam machining or drilling could not form a number of holes at a time, and hence has to form a number of holes one after another, resulting in increased manufacturing cost.

In drilling, chisel edges at the tip of a drill will adversely affect resulting fine holes. In more detail, the chisel edges tend to wobble under the influence of even slight flaws or scratches or unevenness of the surface so that the starting position of the hole would be shifted from the target position and formation of a vertical hole perpendicular to the surface would become impossible.

Although a fine hole perpendicular to the surfaces can be formed using the laser beam machining, its manufacturing cost would go up for the reason described above and due to high expense of the method itself.

The trend in miniaturization of electric and electronic appliances and hence connectors in recent years have been described repeatedly. In order to miniaturize the connectors, spacing between electric contacts must also be narrowed. In the connector as disclosed in the Patent Literature 4, the width of the U-shaped slits about the electric contacts must be narrowed in order to achieve narrower pitches of the electric contacts. Methods for cutting the U-shaped slits may include the laser beam machining and etching. However, both the methods could not cut a slit, such as a U-shaped slit, of a width less than 30 μm. Consequently, the applicant of the present application has proposed the laser beam machining method as disclosed in the Patent Literature 5 to realize perforating and cutting of the order of 20 μm.

However, it is increasingly needed to form a slit of a width narrower than 20 μm in order to achieve a more miniaturized connector.

### SUMMARY OF THE INVENTION

In view of the problems of the prior art described above, it is an object of the invention to provide a method for producing a board formed with through-holes with a high positional accuracy relative to both the surfaces of the board and into which conductors can be inserted and electrically connected, respectively, to comply with customer's requirements.

In view of the problems of the prior art described above, it is another object of the invention to provide electric contacts having a predetermined height (which is as high as possible and uniform) without causing any defective connection between them and a method for producing such electric contacts.

In view of the problems of the prior art described above, it is a further object of the invention to provide electric contact structures which permit a large amount of electric current to flow therein and are adapted to contact a mating object in an optimized manner without increasing manufacturing cost,

In view of the problems of the prior art described above, it is an object of the invention to provide electric contacts which are superior in conductivity and wear-resistance and achieve stable electrical connection and a method for producing such electric contacts.

In view of the problems of the prior art described above, it is another object of the invention to provide a structure for vertically holding conductors, which has holes perpendicular to both surfaces for vertically holding conductors passing through the holes and is inexpensively manufactured, and a connector using such a structure.

In view of the problems of the prior art described above, it is a further object of the invention to provide a laser beam machining method for machining slits having a width W smaller than and a length L longer than a focused laser beam diameter D.

The above objects can be achieved by the method for producing a flexible printed circuit board 14 consisting of a polyimide layer 20 and copper foils 18 and formed with through-holes 22 by working said board 14 from one direction according to the invention as recited in claim 1, comprising steps of forming an acid proof or an acid resistant material layer 38 having a plurality of holes A24 each having a required diameter and located at a predetermined position on one surface of said flexible printed circuit board 14 by printing or attaching an acid proof film onto the one surface, and forming an acid proof material layer 38 on the whole other surface of the board 14 by printing or attaching an acid proof film onto the whole other surface, and exposing and developing and processing with an alkali liquid said acid proof film on said one surface to form a plurality of holes A24 each having a required diameter as a first step; forming a hole B26 in each of the copper foils 18 on said one surface by etching with an acid liquid as a second step, said hole B26 having a required diameter and being at a location corresponding to each of said holes A24 of the flexible printed circuit board 14 in the state obtained in said first step; after removal of the acid proof material layer 38 or acid proof film, forming holes C28 in said polyimide layer 20 by etching with an alkali liquid as a third step, said holes C28 each having a required diameter and being at a location corresponding to each of said holes B26 of the flexible printed circuit board 14 in the state obtained in said second step; attaching an acid proof film onto the surface opening said holes C28 in the state obtained in said third step and forming an acid proof material layer 38 on the other surface by printing or attaching acid proof films on both the surfaces as a fourth step; forming holes D30 in the acid proof film on the surface opening said holes C28 by exposing and developing and processing with an alkali liquid as a fifth step, said holes D30 each having a diameter smaller than that of said hole C28 and being at a location corresponding to said hole C28; forming a member of holes E32 having a required diameter in each of the copper foils 18 corresponding to each of said holes D30 of the flexible printed circuit board 14 in the state obtained in said fifth step by etching with an acid liquid as a sixth step; removing said acid proof film or said acid proof material layer 38 on both the surfaces of the flexible printed circuit board 14 by means of an alkali liquid as a seventh step; and plating predetermined portions of the copper foils 18 on both the sides and inside of each of the through-holes 22 obtained in the above steps to form a continuous plate layer 40 as an eighth step.

Moreover, the above objects can also be achieved by the electric contact 70 extending from a copper foil 90 as recited in claim 2, comprising a metal ball 84 fixed to said copper foil 90 by solidification of a metal paste layer 92 or conductive paste layer coated on said copper foil 90, said metal ball 94 having a noble metal plate layer by plating with the noble metal after the metal ball 94 has been fixed to said copper foil 90, said noble metal plate layer extending over at least a part adapted to contact a mating object, and further by the electric contact extending from a copper foil as recited in claim 3, comprising a metal ball 84, which has been plated with a noble metal, fixed to said copper foil 90 by solidification of a metal paste layer 92 or conductive paste layer coated on said copper foil 90.

If a metal of a high degree of purity is used, the boundary surface of the polycrystalline substance recedes into interior of it. In the electric contact 70 described in claim 6, the metal ball 94 of an alloy is used. It is preferable to use alloys whose unit metal element does not exceed 97%. For example, preferable are copper alloys such as phosphor bronze, beryllium copper and the like.

The electric contact 70 recited in claim 7 is constructed in that said metal ball 94 is fixed to said copper foil 90 by solidification of the metal paste layer 92 or conductive paste layer coated in a through-hole 98 of a cover lay 96 arranged on said copper foil 90.

An opening angle of the through-hole 98 of the cover lay 96 widening upwardly is preferably 30° to 70° in order to firmly fix the metal ball 94 in a stable position.

In order to enhance the holding power for the metal ball, in the electric contact recited in claim 8, after a cover lay 96 having a through-hole 98 has been arranged on said copper foil 90, said through-hole 98 and said cover lay 96 are plated with copper so as to reach at least upper surface of the cover lay 96, and the copper plate layer thus obtained is coated with a metal paste layer 92 or conductive paste layer. Thereafter, said metal ball 94 is fixed to the copper foil 90 by solidification of the metal paste layer 92 or conductive paste layer coated on the copper plate layer.

As described in claim 14, the method for producing an electric contact 70 extending from a copper foil 90 comprises steps of coating said copper foil 90 with a metal paste layer 92 or conductive paste layer over a predetermined area as a first step; loading a metal ball 94 on said metal paste layer 92 or conductive paste layer and thereafter pressing said metal ball 94 against said copper foil 90 as a second step; solidifying said metal paste layer 92 or conductive paste layer at a predetermined temperature to fix said metal ball 94 to said copper foil 90 as a third step; and plating said metal ball 94 with a noble metal over at least part adapted to contact a mating object as a fourth step. As described in claim 15, the method for producing an electric contact 70 extending from a copper foil 90 comprises steps of coating said copper foil 90 with a metal paste layer 92 or conductive paste layer over a predetermined area as a first step; loading a metal ball 94 plated with a noble metal onto said metal paste layer 92 or conductive paste layer and thereafter pressing said metal ball 94 against said copper foil 90 as a second step; and solidifying said metal paste layer 92 or conductive paste layer at a predetermined temperature to fix said metal ball 94 to said copper foil 90 as a third step.

If a metal of a high degree of purity is used, the boundary surface of the polycrystalline substance recedes into interior of it. The method of claim 17 for producing an electric contact 70 uses a metal ball formed by an alloy. It is preferable to use alloys whose unit metal element does not exceed 97%. For example, preferable are copper alloys such as phosphor bronze, beryllium copper and the like.

In the method for producing an electric contact 70 of claim 18, in the step of coating said metal paste 92 or conductive paste layer, a cover lay 96 having a through-hole 98 is arranged on said copper foil 90, and said through-hole 98 is coated with said metal paste layer 92 or conductive paste layer.

An opening angle of the through-hole 98 of the cover lay 96 widening upwardly is preferably 30° to 70°. In this manner, clearances between the metal ball 94 and the cover lay 96 contacting the metal ball 94 are substantially uniform to obtain a uniform joint surface so that the metal ball can be firmly fixed in a stable position by solidification of the metal paste layer.

For the purpose of enhancing the holding forces for the metal ball 94, according to the method for producing an electric contact of claim 19, in the step of coating said metal paste 92 or conductive paste layer, a cover lay 96 having a through-hole 98 is arranged on said copper foil 90, and said through-hole 98 and said cover lay 96 are plated with copper so as to reach at least the upper surface of said cover lay 96 to form a copper plate layer, and further the copper plate layer 96 is coated with said metal paste layer 92 or conductive paste layer.

The above objects can be accomplished by the electric contact structure recited in claim 4, wherein a flexible printed circuit board 114 consisting of a polyimide layer 115 and copper foils 140 arranged on both surfaces of said polyimide layer 115 to embrace it, is formed with a plurality of blind holes 127 at predetermined positions by etching or laser beam machining from the side of one surface of the circuit board 114 to expose the copper foil 140 on the side of the other surface of the circuit board 114 at each of the bottoms of said blind holes 127 and simultaneously therewith the circuit board 114 is formed with through-holes 126, and said copper foils 140 on both the sides, inside of each of said blind holes 127 and inside of each of said through-holes 126 are plated with copper to form a copper plate layer 150 thereon, thereby achieving continuity across said copper foils 140 on both the sides through said blind and through-holes 127 and 126.

In the electric contact structure of claim 9, a contact having a shape adapted to that of a mating object is provided in each of said blind holes 127.

In the electric contact structure of claim 10, a metal ball 144 is fixed in each of said blind holes 127 by solidification of a metal paste 142 or conductive paste.

According to the electric contact structure of claim 11, at least one protrusion contact 145 in the form of a row of mountain is provided on a plate layer provided by plating the inside of said blind hole 127 up to the upper surface of said copper foil.

In the electric contact structure of claim 12, said metal ball 144 or protrusion contact 145 is plated with a noble metal 152 over at least part adapted to contact a mating object.

According to the electric contact structure of claims 13, a cover lay 146 is arranged on said copper plate layer 150 except for said blind and through-holes 127 and 122.

The above object can be achieved by the method for producing an electric contact 220 formed on a copper foil 240 of claim 16 comprising steps of forming a contact 220 of a shape adapted to that of a mating object on said copper foil 240, attaching or arranging a protecting film member 230 onto said contact so as to expose at least part of said contact which is to contact a mating object, applying a conductive hard film 221 to the whole surface of the protecting film member 230, and removing said protecting film member 230 to apply a conductive hard film 221 on said part of the contact to contact the mating object.

The above object can be achieved by the electric contact 220 formed on a copper foil 240 of claim 5, wherein a contact 220 having a shape adapted to the shape of a mating object is formed on said copper foil 240 and a substantially U-shaped slit 222 is formed about said contact 220, an elastomer 216 being arranged under said copper foil 240, and wherein after a protecting film 230 is attached or arranged onto said contact 220 so as to expose at least its contact portion adapted to contact the mating object, a conductive hard film 221 is applied to the whole surface and said protecting film 230 is then removed so that the conductive hard film 221 is applied to at least the contact portion adapted to contact the mating object, and the mating object is slidable on said contact when they are fitted with each other.

The object of the invention can be achieved by the structure for vertically holding conductors 312 recited in claim 20 comprising two plastic sheets 334 each formed with a plurality of inserting holes 336 for inserting a plurality of conductors 312, respectively, said inserting holes 336 each formed with a projection 338 fully circumferentially extending along the inner wall surface of the inserting hole 336 on the side of one surface of the plastic sheet 334, said two plastic sheets 334 being superimposed in an aligned relationship so that said projections 338 are on the sides of the outer surfaces of the two superimposed plastic sheets 334 to form a recess 340 at the center of each of sets of two opposite inserting holes 336 of the sheets 334, and each of the conductors 312 being held by the two projections 338 of each of the sets of two opposite inserting holes 336 of the two superimposed plastic sheets 334.

In recent years, pitches of conductors 312 become increasingly narrower, and the pitches of inserting holes 336 for holding the conductors 312 become also narrower. The sizes of the inserting holes 336 are smaller than those of the conductors 312 for holding the conductors 312 in the holes 336, respectively. In other words, the conductor 312 is held by the inserting hole 336 by a so-called interference fit. Accordingly, when the conductor 312 is held by the whole circumference of the inserting hole 336, the interference extends over the full length of the circumference of the inserting hole 336. Therefore, when the plastic sheet 334 is thin, the expanding stresses of the conductors 312 acting upon the inner circumferences of the inserting holes 336 cause the plastic sheet 334 to be deformed, resulting in warping or undulating.

Therefore, as in claim 21, it is desirable that at least two notches 337 are provided in each of said projections 338 fully circumferentially extending along the inner wall surface of inserting hole 336 on one side of the plastic sheet 334.

The object of the invention can be achieved by the connector 310 of claim 28 comprising two plastic sheets 334 and conductors 312, said two plastic sheets 312 each formed with a plurality of inserting holes 336, said inserting holes 336 each formed with a projection 338 fully circumferentially extending along the inner wall surface of the inserting hole 336 on the side of one surface of the plastic sheet 312, each of said conductors 312 being inserted with one end into the inserting hole 336 of one of the plastic sheets 312 from the side opposite from the projection 338, and then inserted with the other end into the inserting hole 336 of the other plastic sheet 312 from the side opposite from the projection 338 so that said conductors 312 are held by said projections 338 at both the ends of the inner wall surfaces in said inserting holes 336 of the two plastic sheets 312 superimposed in a manner that said projections 338 are on the sides of the outer surfaces of the two superimposed plastic sheets 312, and further comprising an elastomer 316 or elastomers 316 provided on either side, or both sides of said two superimposed plastic sheets 334 and each having holes through which said conductors 312 pass, and a flexible printed circuit board or flexible printed circuit boards 314 provided on either side, or both sides of said elastomers 316 and having through-holes 326 through which said conductors 312 pass and having contacts 320 each adapted to contact a mating object, and said flexible printed circuit board 314 being connected to said conductors 312.

As in claim 29, it is desirable that at least two notches 337 are provided in each of said projections 338 fully circumferentially extending along the inner wall surface of inserting hole 336 on one side of the plastic sheet 312.

As the structure for vertically holding conductors 312 according to the invention, first a conductor 312 is inserted with its one end into the inserting hole 336 of one plastic sheet 334 from the side of the plastic sheet opposite from the projection 338. Then the conductor 312 is inserted with the other end into the inserting hole 336 of the other plastic sheet 334 from the side of the plastic sheet opposite from the projection 338. In this manner, all the conductors 312 are inserted into the inserting holes 336 of both the plastic sheets 334. Thereafter the two plastic sheets 334 are moved toward and contacted to each other under a condition that all the conductors are subjected to tensile forces. In this way, the conductors passing through the two plastic sheets are supported, respectively, by the two projections 338 fully circumferentially extending on the inner walls on the sides of the outer surfaces of the two superimposed plastic sheets 334.

Further, as the structure for vertically holding conductors 312 according to the invention, a mask capable of forming the predetermined inserting holes 336 in the plastic sheet 334 is preferably applied to either of the surfaces of a plastic sheet 334, and a mask is applied to the whole other surface of the plastic sheet 334. Thereafter, the etching process is applied to form the inserting holes 336 in the plastic sheet 334 in a manner that the respective holes 336 each include the projection 338 on the side of the other surface of the plastic sheet 334 to which the overall masking has been applied. Two plastic sheets thus formed with the conductor inserting holes 336 are attached to each other such that the projections 338 are situated on the sides of the outer surfaces of the two attached plastic sheets 334.

In the method for producing the plastic sheet 334, a mask capable of forming the predetermined conductor inserting holes is applied to one of the surfaces of the plastic sheet 334 and further a mask is applied to the whole other surface of the plastic sheet, and the plastic sheet is treated by etching to form the inserting holes 336 each having a projection 338 extending along the full circumference on the inner wall of the inserting hole on the opposite side from the side on which the forming of the inserting holes was started. In the case that an inner diameter of said projections is 1 mm or less, said projections 338 and said notches 337 are preferably formed by etching.

As an approach to comply with the requirement with respect to higher accuracy of vertical positions of the conductors 312, it is envisioned to increase the thickness of the plastic sheet 334. As the inserting holes 336 are formed by etching in the steps of producing the plastic sheet 334, however, the thick plastic sheet makes the whole producing time lengthy to increase the manufacturing cost, and at the same time irregularity in inner diameters of the projections 338 of the inserting holes 336 for holding the conductors 312 increases and hence irregularity in holding forces increases so that the accuracy of the vertically holding the conductor 312 is deteriorated.

Therefore, it is desired to arranged a spacer 335 of a predetermined thickness between the two superimposed plastic sheets 334. The spacer 335 of the predetermined thickness arranged between the two superimposed plastic sheets 334 is preferably used for the connector 310. The term “predetermined thickness” is here understood as signifying a thickness being capable of changing a distance between the two plastic sheets 334 depending upon required accuracy of vertically holding conductors and required overall thickness of the two plastic sheets.

The object of the invention can be achieved by the laser beam machining method for forming a groove or slit having a required width W and a required length L of claim 24 comprising steps of placing on a workpiece 426 a thin stainless steel plate 420 formed with a slit 424 having a width W less than and a length L larger than a focused laser beam diameter D, and moving the laser beam along said slit 424 of said stainless steel plate 420.

The laser beam machining method with a focused laser beam diameter D of 30 μm or more for machining a groove or slit having a required width W and a required length L of claim 25 comprises steps of placing on a workpiece 426 a thin stainless steel plate 420 formed with a slit 424 having a width W less than and a length L larger than said focused laser beam diameter D of 30 μm or more, and moving the laser beam along said slit 424 of said stainless steel plate 420 to form a groove or slit 424 having a width of 30 μm or less in said workpiece 426.

In the laser beam machining method of claim 26, carbon dioxide laser or YAG high frequency laser is used as the laser beam.

In the laser beam machining method of claim 27, instead of the step of placing the thin stainless steel plate, two thin stainless steel plates 420 each having a slit 428 is placed on a workpiece so that their slits 428 are slightly shifted to each other to form a slit 424 having a width W less than and a length L larger than a focused laser beam diameter D, and the laser beam is moved along said slit 424 formed by the shifted slits of said stainless steel plates 420 to form a groove or slit 424 having a width W less than and a length L longer than the focused laser beam diameter D.

The invention can bring about the following significant effects. (1) According to the invention recited in claim 1, the method for producing a flexible printed circuit board 14 consisting of a polyimide layer 20 and copper foils 18 and formed with through-holes 22 by working said board 14 from one direction, comprises steps of forming an acid proof material layer 38 having a plurality of holes A24 each having a required diameter and located at a predetermined position on one surface of said flexible printed circuit board 14 by printing or attaching an acid proof film onto the one surface, and forming an acid proof material layer 38 on the whole other surface of the board 14 by printing or attaching an acid proof film onto the whole other surface, and in the case that said acid proof film is attached to said one surface, exposing and developing and processing with an alkali liquid said acid proof film on said one surface to form a plurality of holes A24 each having a required diameter as a first step; forming a hole B26 in each of the copper foils 18 on said one surface by etching with an acid liquid as a second step, said hole B26 having a required diameter and being at a location corresponding to each of said holes A24 of the flexible printed circuit board 14 in the state obtained in said first step; after removal of the acid proof material layer 38 or acid proof film, forming holes C28 in said polyimide layer 20 by etching with an alkali liquid as a third step, said holes C28 each having a required diameter and being at a location corresponding to each of said holes B26 of the flexible printed circuit board 14 in the state obtained in said second step; attaching an acid proof film onto the surface opening said holes C28 in the state obtained in said third step and forming an acid proof material layer 38 on the other surface by printing or attaching acid proof films on both the surfaces as a fourth step; forming holes D30 in the acid proof film on the surface opening said holes C28 by exposing and developing and processing with an alkali liquid as a fifth step, said holes D30 each having a diameter smaller than that of said hole C28 and being at a location corresponding to said hole C28; forming a hole E32 having a required diameter in each of the copper foils 18 corresponding to each of said holes D30 of the flexible printed circuit board 14 in the state obtained in said fifth step by etching with an acid liquid as a sixth step; removing said acid proof film or said acid proof material layer 38 on both the surfaces of the flexible printed circuit board 14 by means of an alkali liquid as a seventh step; and plating predetermined portions of the copper foils 18 on both the sides and inside of each of the through-holes 22 obtained in the above steps to form a continuous plate layer 40 as an eighth step.

Therefore, according to the invention, a number of holes can be formed at a time, and the working is effected only from one side of the board to avoid misalignment as is the case of forming the holes from both sides of the board, so that the holes are straight and have a perfect circle cross-section, thereby enabling conductors 12 to be inserted therethrough to comply with customers requirements.

(2) According to claim 2, the electric contact 70 extending from a copper foil 90 comprises a metal ball 84 fixed to said copper foil 90 by solidification of a metal paste layer 92 or conductive paste layer coated on said copper foil 90, said metal ball 94 having a noble metal plate layer by plating with the noble metal after the metal ball 94 has been fixed to said copper foil 90, said noble metal plate layer extending over at least a part adapted to contact a mating object.

Consequently, irregularities in heights of a plurality of electric contacts 70 can be avoided, that is, electric contacts 70 are uniform in height so that accurate height of electric contacts 70 fully complying with customer's requirements can be obtained by selecting a diameter of metal balls 94, thereby enabling any defective or failed connection to be prevented.

(3) According to claim 3, the electric contact extending from a copper foil comprises a metal ball 84, which has been plated with a noble metal, fixed to said copper foil 90 by solidification of a metal paste layer 92 or conductive paste layer coated on said copper foil 90.

Therefore, there are no irregularities in heights of a plurality of electric contacts 70, that is, electric contacts 70 are uniform in height so that accurate height of electric contacts 70 fully complying with customer's requirements can be obtained by selecting a diameter of metal balls, thereby enabling any defective or failed connection to be prevented.

(4) According to claim 6, said metal ball 94 is made of an alloy.

Using the alloy, recesses occurring in the boundary surface of the polycrystalline substance as described above can be eliminated, or if not eliminated, the recesses become fine to an extent not causing any problem, and the metal balls become a perfect sphere as a whole to bring about stable electrical connection.

(5) According to claim 7, said metal ball 94 is fixed to said copper foil 90 by solidification of the metal paste layer 92 or conductive paste layer coated in a through-hole 98 of a cover lay 96 arranged on said copper foil 90.

Therefore, the metal ball 94 can be readily arranged in position, and irregularities in heights of a plurality of electric contacts 70 can be avoided, that is, electric contacts 70 are uniform in height so that accurate height of electric contacts 70 can be obtained to comply with customer's requirements, thereby enabling any defective or failed connection to be prevented.

(6) According to claim 8, after a cover lay 96 having a through-hole 98 has been arranged on said copper foil 90, said through-hole 98 and said cover lay 96 are plated with copper so as to reach at least upper surface of the cover lay 96, and the copper plate layer thus obtained is coated with a metal paste layer 92 or conductive paste layer.

Thereafter, said metal ball 94 is fixed to the copper foil 90 by solidification of the metal paste layer 92 or conductive paste layer coated on the copper plate layer. Therefore, the metal ball 94 can be readily arranged in position and there are no irregularities in heights of a plurality of electric contacts 70, that is, electric contacts 70 are uniform in height so that accurate height of electric contacts 70 can be obtained to comply with customer's requirements, thereby enabling the holding force for the metal ball 94 to be increased and enabling any defective or failed connection to be prevented.

(7) According to claim 14, the method for producing an electric contact 70 extending from a copper foil 90 comprises steps of coating said copper foil 90 with a metal paste layer 92 or conductive paste layer over a predetermined area as a first step; loading a metal ball 94 on said metal paste layer 92 or conductive paste layer and thereafter pressing said metal ball 94 against said copper foil 90 as a second step; solidifying said metal paste layer 92 or conductive paste layer at a predetermined temperature to fix said metal ball 94 to said copper foil 90 as a third step; and plating said metal ball 94 with a noble metal over at least part adapted to contact a mating object as a fourth step.

Therefore, there are no irregularities in height of a plurality of electric contacts 70, that is, electric contacts 70 are uniform in height so that accurate height of electric contacts 70 can be obtained to comply with customer's requirements, thereby enabling any defective or failed connection to be prevented.

(8) According to claim 15, the method for producing an electric contact 70 extending from a copper foil 90 comprises steps of coating said copper foil 90 with a metal paste layer 92 or conductive paste layer over a predetermined area as a first step; loading a metal ball 94 plated with a noble metal onto said metal paste layer 92 or conductive paste layer and thereafter pressing said metal ball 94 against said copper foil 90 as a second step; and solidifying said metal paste layer 92 or conductive paste layer at a predetermined temperature to fix said metal ball 94 to said copper foil 90 as a third step. Consequently, there are no irregularities in height of a plurality of electric contacts 70, that is, electric contacts 70 are uniform in height so that accurate height of electric contacts 70 can be obtained to comply with customer's requirements, thereby enabling any defective or failed connection to be prevented.

(9) According to claim 17, the method for producing an electric contact uses a metal ball formed by an alloy.

Using the alloy, recesses occurring in the boundary surface of the polycrystalline substance as described above can be eliminated, or if not eliminated, the recesses become fine to an extent not causing any problem and the metal balls become a perfect sphere as a whole to bring about stable electrical connection.

(10) In the method for producing an electric contact 70 according to claim 18, in the step of coating said metal paste 92 or conductive paste layer, a cover lay 96 having a through-hole 98 is arranged on said copper foil 90 and said through-hole 98 is coated with said metal paste layer 92 or conductive paste layer.

Therefore, the metal ball 94 can be readily arranged in the prescribed position and irregularities in heights of a plurality of electric contacts 70 can be avoided, that is, electric contacts 70 are uniform in height so that accurate height of electric contacts 70 can be obtained to comply with customer's requirements, thereby enabling any defective or failed connection to be prevented.

(11) In the method for producing an electric contact 70 according to claim 19, in the step of coating said metal paste 92 or conductive paste layer, a cover lay 96 having a through-hole 98 is arranged on said copper foil 90, and said through-hole 98 and said cover lay 96 are plated with copper so as to reach at least the upper surface of said cover lay 96 to form a copper plate layer. And the copper plate layer 96 is coated with said metal paste layer 92 or conductive paste layer.

Consequently, the metal ball 94 can be readily arranged in the prescribed position and there are no irregularities in heights of a plurality of electric contacts 70, that is, electric contacts 70 are uniform in height so that accurate height of electric contacts 70 can be obtained to comply with customer's requirements, thereby enabling the holding force for the metal ball 94 to be increased and enabling any defective or failed connection to be prevented.

(12) In the electric contact structure of claim 4, a flexible printed circuit board 114 consisting of a polyimide layer 115 and copper foils 140 arranged on both surfaces of said polyimide layer 115 to embrace it, is formed with a plurality of blind holes 127 at predetermined positions by etching or laser beam machining from the side of one surface of the circuit board 114 to expose the copper foil 140 on the side of the other surface of the circuit board 114 at each of the bottoms of said blind holes 127 and simultaneously therewith the circuit board 114 is formed with through-holes 126, and said copper foils 140 on both the sides, inside of each of said blind holes 127 and inside of each of said through-holes 126 are plated with copper to form a copper plate layer 150 thereon, thereby achieving continuity across said copper foils 140 on both the sides through said blind and through-holes 127 and 126.

Accordingly, the electric contacts permit a large amount of electric current to flow therein and enable a reduced overall height of a connector without increasing manufacturing cost. As the circuits are configured as to receive one signal by two circuits, the reliability and redundancy in good sense are duplicated even in an unlikely event of disconnection of copper foil circuit.

(13) In the electric contact structure of claim 9, a contact having a shape adapted to that of a mating object is provided in each of said blind holes 127.

Consequently, the electric contacts can be optimized for mating objects and permit a large amount of electric current to flow therein and enable a reduced overall height of a connector without increasing manufacturing cost. As the circuits are configured as to receive one signal by two circuits, the reliability and redundancy in good sense are duplicated even in an unlikely event of disconnection of copper foil circuit.

(14) In the electric contact structure of claim 10, a metal ball 144 is fixed in each of said blind holes 127 by solidification of a metal paste 142 or conductive paste.

Accordingly, the electric contacts can be optimized for mating objects and permit a large amount of electric current to flow therein and enable a reduced overall height of a connector 110 without increasing manufacturing cost. As the circuits are configured as to receive one signal by two circuits, the reliability and redundancy in good sense are duplicated even in an unlikely event of disconnection of copper foil circuit.

(15) In the electric contact structure of claim 11, at least one protrusion contact 145 in the form of a row of mountain is provided on a plate layer provided by plating the inside of said blind hole 127 up to the upper surface of said copper foil.

Consequently, the electric contacts can be optimized for mating objects and permit a large amount of electric current to flow therein and enable a reduced overall height of a connector 110 without increasing manufacturing cost. As the circuits are configured as to receive one signal by two circuits, the reliability and redundancy in good sense are duplicated even in an unlikely event of disconnection of copper foil circuit.

(16) In the electric contact structure of claim 12, said metal ball 144 or protrusion contact 145 is plated with a noble metal 152 over at least part adapted to contact a mating object.

Accordingly, the stable continuity can be achieved.

(17) In the structure of electric contacts of claim 13, a cover lay 146 is arranged on said copper plate layer 150 except for said blind and through-holes 127 and 122.

Therefore, the electric contacts can be optimized for mating objects and permit a large amount of electric current to flow therein and enable a reduced overall height of a connector 110 without increasing manufacturing cost. As the circuits are configured as to receive one signal by two circuits, the reliability and redundancy in good sense are duplicated even in an unlikely event of disconnection of copper foil circuit, and the holding force for the metal ball 144 can be increased.

(18) The method for producing an electric contact 220 formed on a copper foil 240 of claim 16 comprises steps of forming a contact 220 of a shape adapted to that of a mating object on said copper foil 240, attaching or arranging a protecting film member 230 onto said contact so as to expose at least part of said contact which is to contact a mating object, applying a conductive hard film 221 to the whole surface of the protecting film member 230, and removing said protecting film member 230 to apply a conductive hard film 221 on said part of the contact to contact the mating object.

Therefore, the electric contacts according to the invention are superior in conductivity and wear resistance without causing dust and dirt accumulation, thereby achieving stable electrical connection.

(19) In the electric contact 220 each formed on a copper foil 240 of claim 5, wherein a contact 220 having a shape adapted to the shape of a mating object is formed on said copper foil 240 and a substantially U-shaped slit 222 is formed about said contact 220, an elastomer 216 being arranged under said copper foil 240, and wherein after a protecting film 230 is attached or arranged onto said contact 220 so as to expose at least its contact portion adapted to contact the mating object, a conductive hard film 221 is applied to the whole surface and said protecting film 230 is then removed so that the conductive hard film 221 is applied to at least the contact portion adapted to contact the mating object, and the mating object is slidable on said contact when they are fitted with each other.

Consequently, the electric contacts according to the invention are easily slidably movable and superior in conductivity and wear resistance without causing dust and dirt accumulation, thereby achieving stable electrical connection.

(20) The structure for vertically holding conductors 312 recited in claim 20 comprises two plastic sheets 334 each formed with a plurality of inserting holes 336 for inserting a plurality of conductors 312, respectively, said inserting holes 336 each formed with a projection 338 fully circumferentially extending along the inner wall surface of the inserting hole 336 on the side of one surface of the plastic sheet 334, said two plastic sheets 334 being superimposed in an aligned relationship so that said projections 338 are on the sides of the outer surfaces of the two superimposed plastic sheets 334 to form a recess 340 at the center of each of sets of two opposite inserting holes 336 of the sheets 334, and each of the conductors 312 being held by the two projections 338 of each of the sets of two opposite inserting holes 336 of the two superimposed plastic sheets 334.

Accordingly, the conductors 312 are supported by both the ends of the inner walls of the inserting apertures 36 of the plastic sheets so that the conductors 12 can be securely and vertically held.

(21) In the structure for vertically holding conductors 312 recited in claim 21, at least two notches 337 are provided in each of said projections 338 fully circumferentially extending along the inner wall surface of inserting hole 336 on one side of the plastic sheet 334.

Consequently, this vertically holding structure can tolerate narrower pitches of the inserting holes 336 and increased number of conductors 312 and can securely hold conductors 312 without causing deformation of the plastic sheets 334.

(22) The connector 310 of claim 28 comprises two plastic sheets 334 and conductors 312, said two plastic sheets 312 each formed with a plurality of inserting holes 336, said inserting holes 336 each formed with a projection 338 fully circumferentially extending along the inner wall surface of the inserting hole 336 on the side of one surface of the plastic sheet 312, each of said conductors 312 being inserted with one end into the inserting hole 336 of one of the plastic sheets 312 from the side opposite from the projection 338, and then inserted with the other end into the inserting hole 336 of the other plastic sheet 312 from the side opposite from the projection 338 so that said conductors 312 are held by said projections 338 at both the ends of the inner wall surfaces in said inserting holes 336 of the two plastic sheets 312 superimposed in a manner that said projections 338 are on the sides of the outer surfaces of the two superimposed plastic sheets 312, and further comprising an elastomer 316 or elastomers 316 provided on either side, or both sides of said two superimposed plastic sheets 334 and each having holes through which said conductors 312 pass, and a flexible printed circuit board or flexible printed circuit boards 314 provided on either side, or both sides of said elastomers 316 and having through-holes 326 through which said conductors 312 pass and having contacts 320 each adapted to contact a mating object, and said flexible printed circuit board 314 being connected to said conductors 312.

Therefore, the connector includes a circuit board having holes accurately vertical to its surfaces to enable the conductors 312 to be vertically held with ease and can achieve miniaturization and narrower pitches, and at the same time can accomplish stable electrical connection.

(23) In the connector 310 of claim 29, at least two notches 337 are provided in each of said projections 338 fully circumferentially extending along the inner wall surface of inserting hole 336 on one side of the plastic sheet 312.

Consequently, this vertically holding structure can tolerate narrower pitches of the inserting holes 336 and increased number of conductors 312 and can securely hold conductors 312 perpendicularly to both the surfaces without causing deformation of the plastic sheets 334.

(24) In the structure for vertically holding conductors, first a conductor 312 is inserted with its one end into the inserting hole 336 of one plastic sheet 334 from the side of the plastic sheet opposite from the projection 338. Then the conductor 312 is inserted with the other end into the inserting hole 336 of the other plastic sheet 334 from the side of the plastic sheet opposite from the projection 338. In this manner, all the conductors 312 are inserted into the inserting holes 336 of both the plastic sheets 334. Thereafter the two plastic sheets 334 are moved toward and contacted to each other under a condition that all the conductors are subjected to tensile forces. In this way, the conductors passing through the two plastic sheets are supported by the two projections 338, respectively.

Accordingly, the conductors 312 can be held in a simple manner. Since the conductors 312 are held by both the ends of the inner wall surfaces of the inserting holes 336 of the plastic sheets 334, the conductors 312 can be securely and vertically held.

(25) According to the structure for vertically holding conductors 312 of the invention, a mask capable of forming the predetermined inserting holes in the plastic sheet is preferably applied to either of the surfaces of a plastic sheet 334, and a mask is applied to the whole other surface of the plastic sheet. Thereafter, the etching process is applied to form the inserting holes 336 in the plastic sheet 334 in a manner that the respective holes 336 each include the projection 338 on the side of the other surface of the plastic sheet 334 to which the overall masking has been applied. Two plastic sheets thus formed with the conductor inserting holes 336 are attached to each other such that the projections 338 are situated on the sides of the outer surfaces of the two attached plastic sheets 334.

Therefore, the plastic sheets 334 are easily worked, and the conductors 312 can be held in a simple manner. Since the conductors 312 are held by both the ends of the inner wall surfaces of the inserting holes 336 of the plastic sheets 334, the conductors 312 can be securely and vertically held.

(26) A mask capable of forming the predetermined conductor inserting holes is applied to one of the surfaces of the plastic sheet 334 and further a mask is applied to the whole other surface of the plastic sheet 334, and the plastic sheet is treated by etching to form the inserting holes 336 so that projections 338 each extend along the full circumference on the inner wall of each of the inserting holes on the opposite side from the side on which the forming of the inserting holes was started.

According to the invention, a number of exactly vertical holes can be formed inexpensively at a time without increasing manufacturing cost so that conductors 312 can be vertically held with ease.

(27) In the vertical holding structure for conductors of claim 23, as a spacer 335 of a required thickness is arranged between two superimposed plastic sheets 334, the conductor holding sheets 334 on upper and lower sides can be made thinner so that inner diameters of the projections 338 of the inserting holes 336 for holding the conductors 312 can be formed without irregularities because cutting thickness becomes less.

Accordingly, holding forces for the conductors 312 are uniform without irregularities to securely hold the conductors vertically. The plastic sheets 334 can be worked for a short time, thereby restraining the manufacturing cost.

(28) According to the invention, arranged between two superimposed plastic sheets 334 for use in a connector 310 is a spacer of a required thickness determined according to required accuracy of vertically held conductors and required overall thickness, so that the inner diameters of the projections 338 of the inserting holes 336 for holding the conductors 312 can be worked without irregularities, and hence irregularities in holding force for conductors are not caused, thereby securely holding the conductors 312 vertically. The plastic sheets 334 can be worked for a short period of time without increasing the manufacturing cost.

(29) The laser beam machining method for forming a groove or slit having a required width W and a required length L of claim 24, comprises steps of placing on a workpiece 426 a thin stainless steel plate 420 formed with a slit 424 having a width W less than and a length L larger than a focused laser beam diameter D, and moving the laser beam along said slit 424 of said stainless steel plate 420.

Therefore, slits can be easily formed, which have a width W less than and a length L large than the focused laser beam diameter D.

(30) The laser beam machining method with a focused laser beam diameter D of 30 μm or more for machining a groove or slit having a required width W and a required length L of claim 25, comprises steps of placing on a workpiece 426 a thin stainless steel plate 420 formed with a slit 424 having a width W less than and a length L larger than said focused laser beam diameter D of 30 μm or more, and moving the laser beam along said slit 424 of said stainless steel plate 420 to form a groove or slit 424 having a width of 30 μm or less in said workpiece 426. Accordingly, slits can be easily formed, which have a width W less than and a length L large than the focused laser beam diameter D.

(31) In the laser beam machining method of claim 26, carbon dioxide laser or YAG high frequency laser is used as the laser beam. Even with inexpensive carbon dioxide laser or YAG high frequency laser, slits can be easily formed, which have a width W less than and a length L large than the focused laser beam diameter D.

(32) In the laser beam machining method of claim 27, instead of the step of placing the thin stainless steel plate, two thin stainless steel plates 420 each having a slit 428 are placed on a workpiece so that their slits 428 are slightly shifted to each other to form a slit 424 having a width W less than and a length L larger than a focused laser beam diameter D, and the laser beam is moved along said slit 424 formed by the shifted slits of said stainless steel plates 420 to form a groove or slit 424 having a width W less than and a length L longer than the focused laser beam diameter D.

Consequently, slits can be easily formed, which have a width W less than and a length L large than the focused beam diameter D.

The invention will be more fully understood by referring to the following detailed specification and claims taken in connection with the appended drawings.

### BRIEF DESCRIPTION OF THE DRAWINGS

FIGS. 1A to 1H are views for explaining a method for producing a board formed with through-holes;

FIG. 2 is an enlarged view of a fine conductor inserted into the through-hole of the board produced by the method shown in FIGS. 1A to 1H;

FIG. 3A is a partly enlarged plan view of a connector using the boards produced by the method shown in FIGS. 1A to 1H;

FIG. 3B is a partly enlarged cross-sectional view of the connector shown in FIG. 3A;

FIG. 4A is a view illustrating the configuration of an electric contact according to the invention;

FIG. 4B is a view illustrating the configuration of another electric contact using a cover lay according to the invention;

FIG. 4C is a view for explaining the opening angle of the cover lay;

FIG. 5 is a view including a plan and a longitudinal sectional view of an electrical connector using the electric contacts shown in FIG. 4A or 4B according to the invention;

FIG. 6 is a view including a partly enlarged plan and a longitudinal sectional view of the connector shown in FIG. 5;

FIGS. 7A to 7D are views for explaining the method for producing an electric contact according to the invention;

FIGS. 8A to 7D are views for explaining the method for producing an electric contact using a cover lay according to the invention;

FIG. 9 is a view illustrating the configuration of a further electric contact according to the invention;

FIGS. 10A to 10D are views for explaining a producing method for the electric contact shown in FIG. 9;

FIG. 11 is a view for explaining a electric contact structure according to the invention;

FIG. 12A is a sectional view for explaining the electric contact structure in which a metal ball is arranged in a blind hole;

FIG. 12B is a sectional view for explaining the electric contact structure in which a protrusion contact is arranged in a blind hole;

FIG. 12C is a sectional view taken along the line A-A in FIG. 12B;

FIG. 13 is a partly sectional view of a connector having a protrusion contact arranged in each of blind holes on one surface and a metal ball arranged in each of blind holes on the other surface;

FIGS. 14A and 14B are views illustrating electric contacts of the prior art, respectively;

FIG. 15A is a partly sectional view of an electric contact according to the invention;

FIG. 15B is a partly sectional view of the electric contact shown in

FIG. 15A to which dry films are attached as a protecting film member;

FIG. 15C is a partly sectional view of the electric contact shown in FIG. 15B with conductive hard films by spraying;

FIG. 15D is a partly sectional view of the electric contact shown in FIG. 15C with the dry films as the protecting film removed;

FIG. 16A is a sectional view of another electric contact according to the invention;

FIG. 16B is a partly sectional view of the electric contact shown in FIG. 16A using dry films and stainless steel plates as protecting films;

FIG. 16C is a partly sectional view of the electric contact shown in FIG. 16B to which conductive hard films are attached by spraying;

FIG. 16D is a partly sectional view of the electric contact shown in FIG. 16C with the dry films and stainless steel plates removed;

FIGS. 17A to 17C are views for explaining shapes of the electric contacts according to the invention;

FIG. 18 is a sectional view of an electrical connector using the above electric contacts;

FIG. 19A is a view illustrating a structure for vertically holding conductors by two plastic sheets according to the invention;

FIG. 19B is a view illustrating a structure similar to that shown in FIG. 19A with modified projections;

FIGS. 20A to 20C are views for explaining a method for producing plastic sheets for use in the structure shown in FIG. 19A;

FIGS. 21A to 21C are view for explaining an assembling method for vertically holding conductors according to the invention;

FIG. 22 is a view including a plan and a cross-sectional view of a connector using the above plastic sheets;

FIG. 23A is a partly enlarged plan view of the connector shown in FIG. 22;

FIG. 23B is a partly enlarged sectional view taken along the line A-A in FIG. 23A;

FIGS. 24A to 24E are views for explaining shapes of notches of projections for holding conductors according to the invention;

FIG. 25 is a view illustrating a structure with a spacer arranged between the two plastic sheets to enlarge the holding distance for the vertically held conductor;

FIG. 26A is a plan view illustrating a state that laser beam impinges against a workpiece in laser beam machining method according to the invention;

FIG. 26B is a sectional view of a part to which laser beam has impinged as shown in FIG. 26A;

FIGS. 27A to 27C are views for explaining shapes to be machined by laser beam according to the invention;

FIG. 28A is a plan view illustrating a state that laser beam impinges against work using a mask different from that in FIG. 26A;

FIG. 28B is a sectional view of a part to which laser beam impinges as shown in FIG. 28A;

FIG. 29A is a partly enlarged plan view of an electrical connector having parts machined by the method illustrated above; and

FIG. 29B is a partly enlarged cross-sectional view of the connector shown in FIG. 29A.

### DESCRIPTION OF THE PREFERRED EMBODIMENTS

First, the production method of the through hole of claim 1 will be explained.

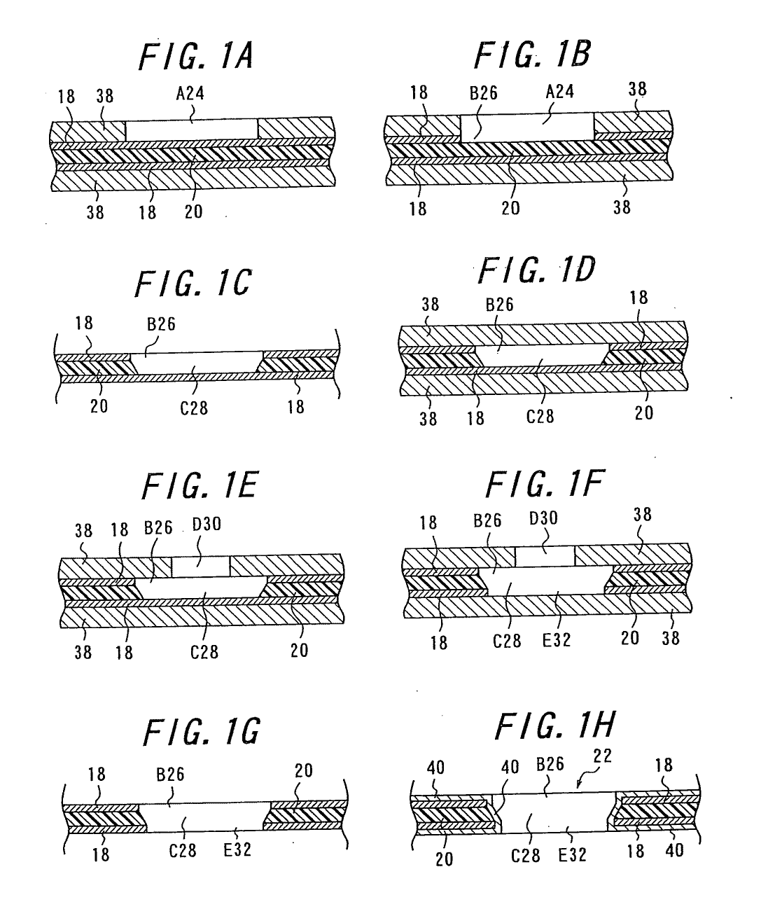

The method for producing a board formed with through-holes 22 according to the invention will be explained with reference to FIGS. 1A to 1H. FIGS. 1A to 1H are drawings for explaining the method for producing the board formed with the through-holes. The method for producing the board formed with the through-holes 22 is carried out in the following steps in which a flexible printed circuit board 14 consisting of a polyimide layer 20 and copper foils 18 and is worked in one direction from its one surface.

In the first step, as shown in FIG. 1A an acid proof material layer 38 having a plurality of holes A24 each having a required diameter and located at a predetermined position is formed by printing on one surface of the board 14, or an acid proof film is attached to the one surface, and an acid proof material layer 38 is formed by printing on the whole other surface of the board 14, or an acid proof film is attached to the whole other surface. In the case that the acid proof film is attached to the one surface of the board 14, as the holes A24 have not been formed, the acid proof film on the one surface of the board 14 is formed with a plurality of holes A24 each having a required diameter by exposing and developing and processed by an alkali liquid.

In the second step, as shown in FIG. 1B each of the copper foils 18 on the one surface is formed with a hole B26 by etching with an acid liquid. The hole B26 has a required diameter and is at the location corresponding to each of the holes A24 of the board 14 in the state obtained in the first step.

In the third step, as shown in FIG. 1C after the acid proof material layers 38 have been removed, the polyimide layer 20 is formed with holes C28 by etching with an alkali liquid. The holes C28 each have a required diameter and are each at a location corresponding to each of the holes B26 in the state obtained in the second step.

In the fourth step, as show in FIG. 1D an acid proof film is attached to the surface on the side opening the holes C28 in the state obtained in the third step, and an acid proof material layer 38 is formed by printing OR the other surface. Otherwise, acid proof films may be attached to both the surfaces.

In the fifth step, as shown in FIG. 1E the acid proof film on the one surface of the board is formed with holes D30 by exposing and developing and processing with an alkali liquid, each of which is smaller in diameter than and at a location corresponding to each of the holes C28.

In the sixth step, as shown in FIG. 1F each of the copper foils 18 is formed with a hole E32 by etching with an acid liquid, The hole E32 has a required diameter and is at a location corresponding to each of the holes D30 in the state obtained in the fifth step.

In the seventh step, as shown in FIG. 1G the acid proof film and the acid proof material layer 38 or the acid proof films on both the surfaces of the circuit board 14 are removed by an alkali liquid.

In the eighth step, as shown in FIG. 1H predetermined portions of the surfaces of the both copper foils 18 and the inner surface of each of the though-holes E32 are continuously plated with a metal. In this way, through-holes 22 are formed in the board.

Further explaining the above eight steps, in the first step, an acid proof material layer 38 having a plurality of holes A24 each having a required diameter and located at a predetermined position is formed by printing on one surface of the board 14, or an acid proof film is attached to the one surface, and an acid proof material layer 38 is formed by printing on the whole other surface of the board 14, or an acid proof film is attached to the whole other surface. In the case that the acid proof film is attached to the one surface of the board 14, since the holes A24 have not been formed, the acid proof film on the one surface of the board 14 is formed with a plurality of holes A24 each having a required diameter by exposing and developing and processed with an alkali liquid. The size of the holes A24 may be suitably designed according to customer's requirements, pitches of the holes, and sizes of objects to be inserted into the through-holes 22. As the alkali liquid, a weak alkali liquid is used in the illustrated embodiment.

In the second step, each of the copper foils 18 on the one surface is formed with a hole B26 by etching with an acid liquid. The hole B26 has a required diameter and is at the location corresponding to each of the holes A24 of the board 14 in the state obtained in the first step. The size of the holes B26 may be suitably designed according to customer's requirements, pitches of the holes, and sizes of objects to be inserted into the through-holes 22.

In the third step, after the acid proof material layers 38 have been removed, the polyimide layer 20 is formed with holes C28 by etching with an alkali liquid. The holes C28 each have a required diameter and are each at a location corresponding to each of the holes B26 in the state obtained in the second step. As the alkali liquid, a strong alkali liquid is used in the illustrated embodiment. The size of the holes C28 may be suitably designed according to customer's requirements, pitches of the holes, and sizes of objects to be inserted into the through-holes 22.

In the fourth step, as shown in FIG. 1D an acid proof film is attached to the surface on the side opening the holes C28 in the state obtained in the third step, and an acid proof material layer 38 is formed by printing on the other surface. Otherwise, acid proof films may be attached to both the surfaces.

In the fifth step, as shown in FIG. 1E the acid proof film on the one surface of the board is formed with holes D30 by exposing and developing and processing with an alkali liquid, each of which is smaller in diameter than and at a location corresponding to each of the holes C28. As the alkali liquid, a weak alkali liquid is used in the illustrated embodiment. The size of the holes D30 may be suitably designed according to customer's requirements, pitches of the holes, and sizes of objects to be inserted into the through-holes 22.

In the sixth step, as shown in FIG. 1F each of the copper foils 18 is formed with a hole E32 by etching with an acid liquid. The hole E32 has a required diameter and is at a location corresponding to each of the holes D30 in the state obtained in the fifth step. The size of the holes E32 may be suitably designed according to customer's requirements, pitches of the holes, and sizes of objects to be inserted into the through-holes 22.

In the seventh step as shown in FIG. 1G, the acid proof film and the acid proof material layer 38 or the acid proof films on both the surfaces of the circuit board 14 are removed by an alkali liquid.

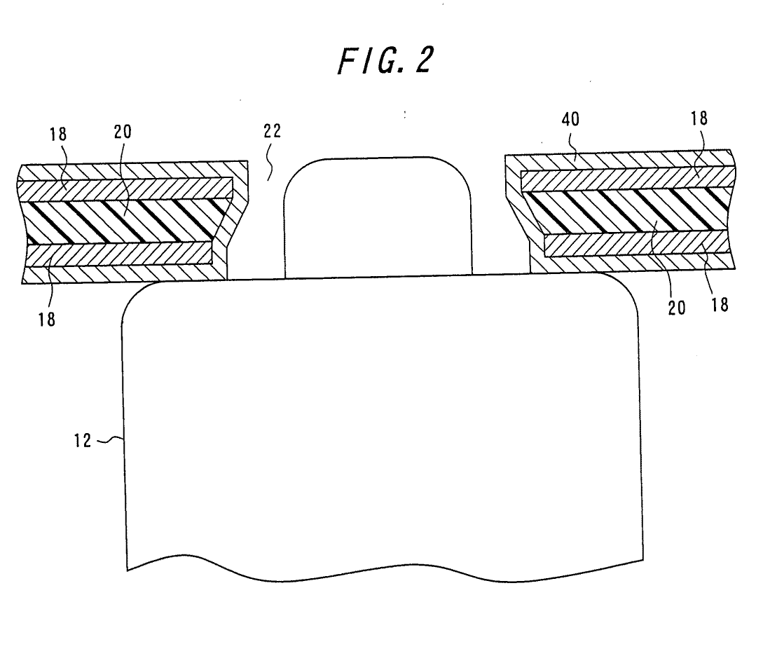

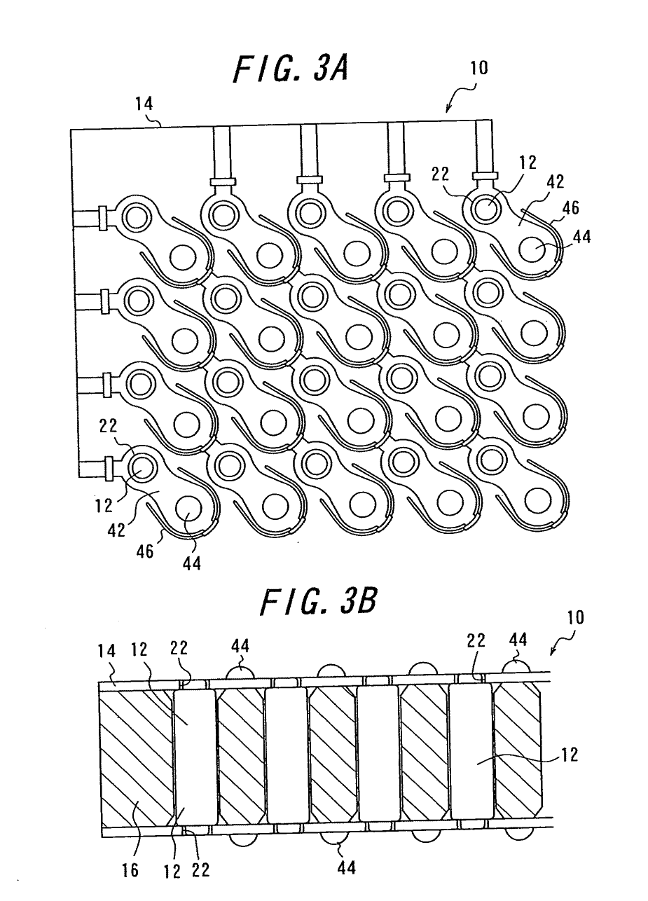

In the eighth step, as shown in FIG. 1H predetermined portions of the surfaces of the both copper foils 18 and the inner surface of each of the though-holes E32 are continuously plated with a metal. A connector using the flexible printed circuit boards 14 formed with the through-holes 22 thus produced will be explained later referring to FIGS. 2 to 3B.

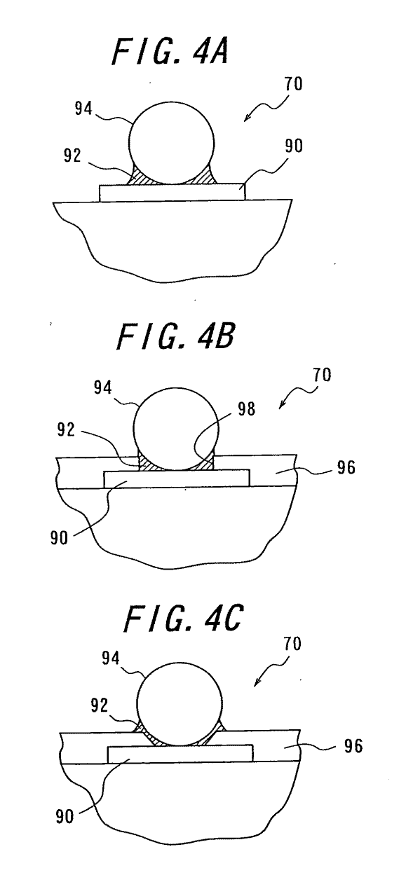

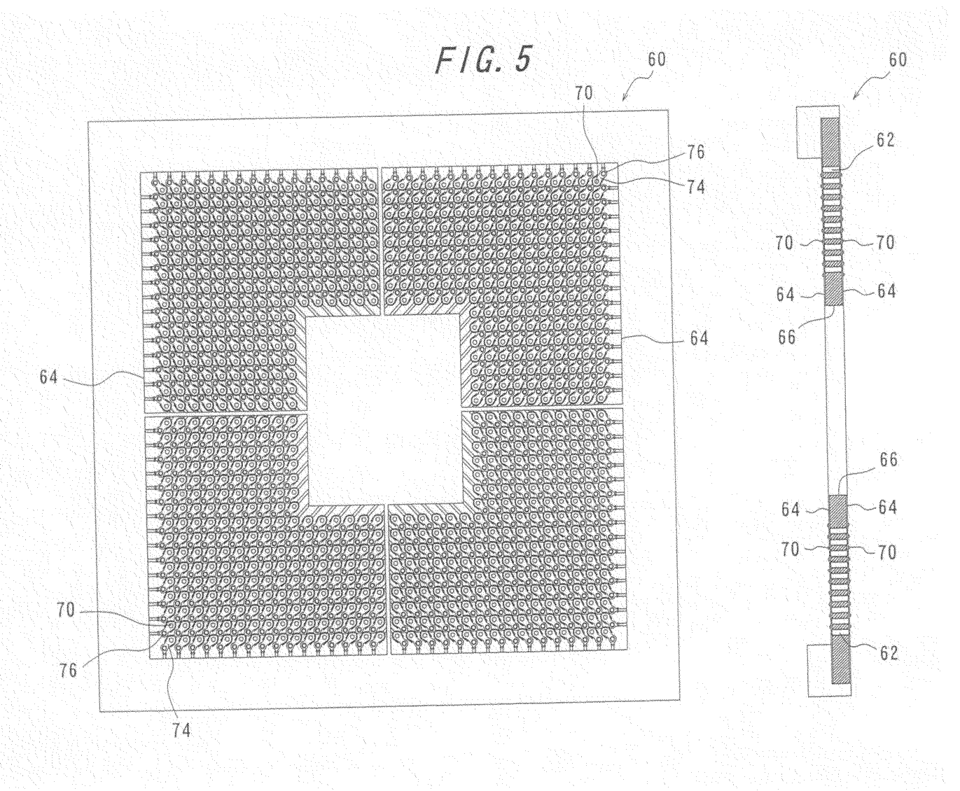

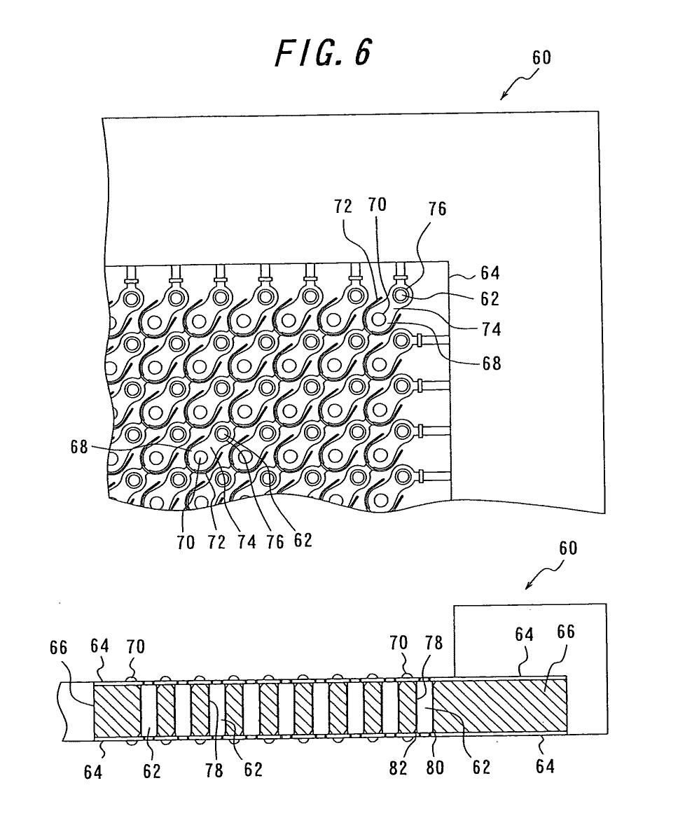

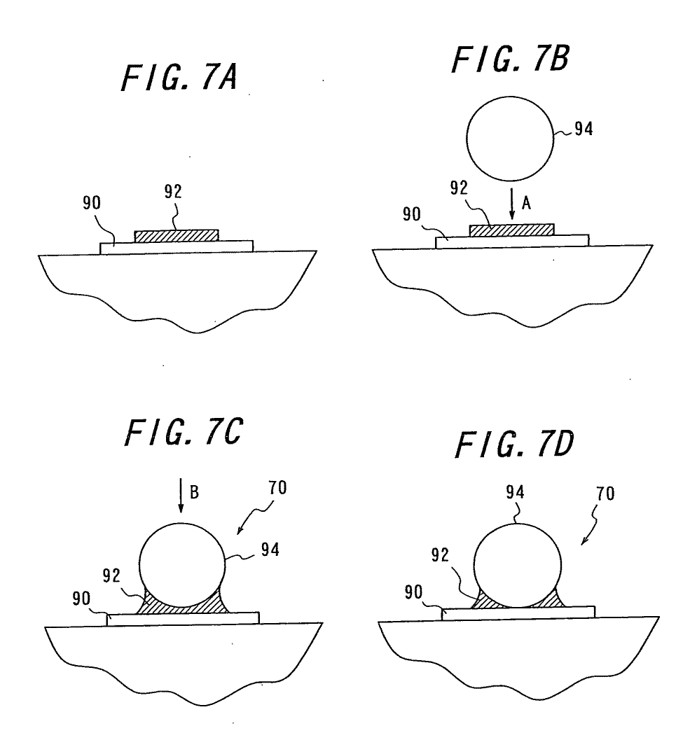

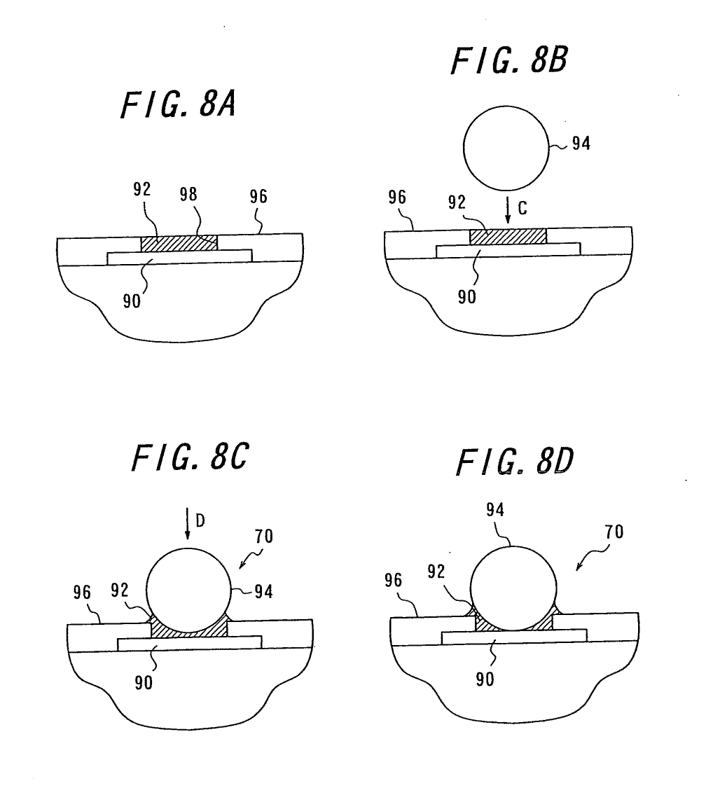

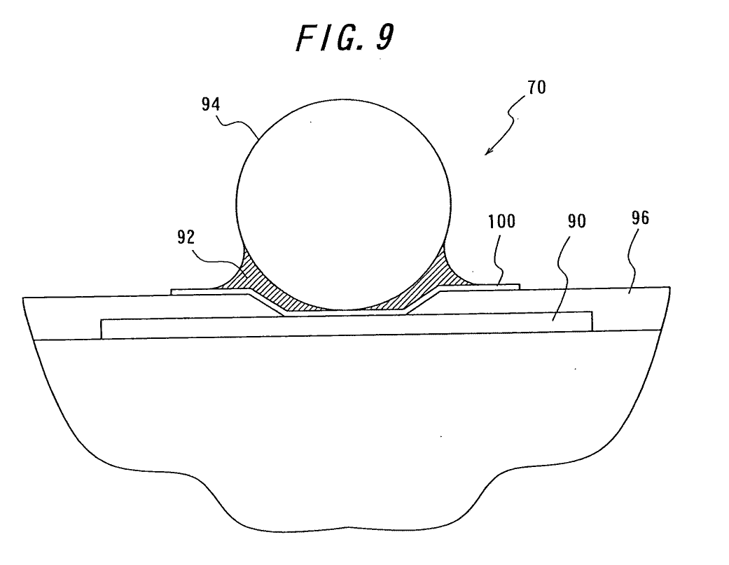

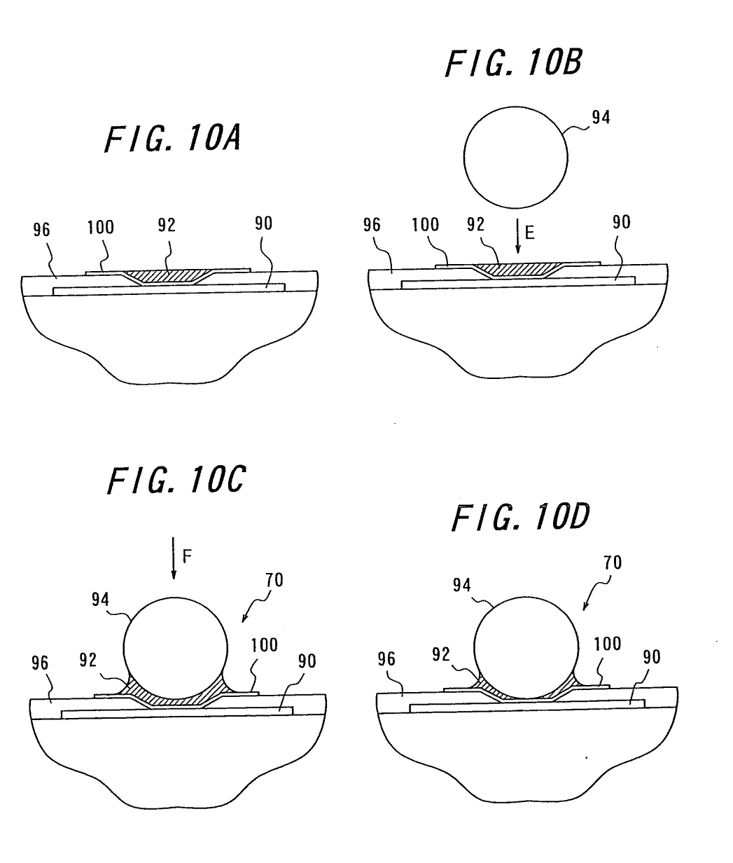

The configuration of electric contacts 70 according to the invention will be explained with reference to FIGS. 4A to 10D. FIG. 4A is a view illustrating the configuration of the electric contact according to the invention, and FIG. 4B is a view illustrating the configuration of the electric contact shown in FIG. 4A with a cover lay. FIG. 4C is a view for explaining the opening angle of the cover lay. FIG. 5 is a view illustrating an electrical connector using such electric contacts in a plan and a longitudinal sectional view. FIG. 6 is a view illustrating the electrical connector in a plan and a partly enlarged longitudinal sectional view. FIGS. 7A to 7D are views for explaining the method for producing the electric contact according to the invention, FIGS. 8A to 8D are views for explaining the method for producing the electric contact according to the invention using a cover lay. FIG. 9 is a view illustrating the configuration of another electric contact. FIGS. 10A to 10D are views for explaining the method for producing the electric contact shown in FIG. 9.

Next, the electric contact will be explained.

First, the electric contact of claims 2 and 3 and claims 6-8 will be explained.

The configuration of the electric contact 70 will be explained with reference to FIG. 4A. The electric contact 70 is made by fixing a metal ball 94 to a copper foil 90 by solidifying a metal paste layer 92 or conductive paste layer. The metal ball 94 is partly plated with gold over at least a contact portion adapted to contact a mating connector. The metal of the metal ball 94 may be suitably selected in consideration of electric conductivity, easiness of surface treatment, sphericity as a whole to be obtained and the like. Alloys are preferable for the metal ball 94, more particularly, whose metal element is not more than 97% in amount, for example, copper alloys such as phosphor bronze and beryllium copper. The size of the metal ball 94 may be suitably designed in consideration of environmental space and required height of the contact.

By way of example, after the metal ball 94 has been fixed to the copper foil 90 by solidification of a metal paste, at least the part of the metal ball adapted to contact the mating connector is gold-plated in the illustrated embodiment in FIG. 4A. Otherwise, after gold-plating, the metal ball 94 may be fixed to the copper foil 90.

A configuration of an electric contact 70 with a cover lay 96 will be explained with reference to FIG. 4B. Explaining the electric contact 70 shown in FIG. 4B, a cover lay 96 having a through-hole 98 of a predetermined size is arranged on a copper foil 90, and the through-hole 98 is filled with a metal paste layer 92 or conductive paste layer. A metal ball 94 is placed on the copper foil and the metal paste layer 92 is then solidified. Of course, the metal ball 94 is partly gold-plated at the portion adapted to contact a mating connector. Although explaining one electric contact, it is of course possible to produce a number of electric contacts at a time using a cover lay having a number of through-holes. The material and size of the metal ball 94 and the metal paste layer 92 or conductive paste layer will not be described in further detail since they are similar to those described in connection with FIG. 4A. FIG. 4B illustrates the metal ball 94, by way of example, in that after the metal ball 94 has been fixed to the copper foil 90 by solidification of a metal paste, at least the part of the metal ball adapted to contact the mating connector is gold-plated. Otherwise, after gold-plating, the metal ball 94 may be fixed to the copper foil 90.

An opening angle of the through-hole 98 of the cover lay 96 widening upwardly viewed in the drawing is preferably 30° to 70° in order to fix the metal ball 94 in position by solidification of the metal paste layer in a settled and balanced manner as shown in FIG. 4C.

A configuration of a further electric contact 70 according to the invention will then be explained with reference to FIG. 9. The electric contact 70 shown in FIG. 9 is produced in the following manner. After a cover lay 96 having a through-hole 98 of a predetermined size has been arranged on a copper foil 90, the through-hole 98 and the upper surface of the cover lay 96 are plated with copper to reach the upper surface of the cover lay 96 to form copper plate layer 100. The copper plate layer 100 is coated with a metal paste layer 92 or conductive paste layer, and thereafter a metal ball 94 is fixed onto the copper plate layer 100 by solidification of the metal paste layer 92. The metal ball 94 is plated with gold over at least part adapted to a mating connector. FIG. 9 illustrates the metal ball 94, by way of example, in that after the metal ball 94 has been fixed to the copper plate layer 100 by solidification of a metal paste, at least the part of the metal ball adapted to contact the mating connector is gold-plated. Otherwise, after gold-plating, the metal ball 94 may be fixed to the copper foil 90. The material and size of the metal ball 94 and the metal paste layer 92 or conductive paste layer will not be described in further detail since they are similar to those just described.

An opening angle of the through-hole 98 of the cover lay 96 widening upwardly viewed in the drawing is preferably 30° to 70° in order to fix the metal ball 94 in position by solidification of the metal paste layer in a settled and balanced manner. A connector using the electric contacts thus produced will be explained later referring to FIGS. 5 and 6.

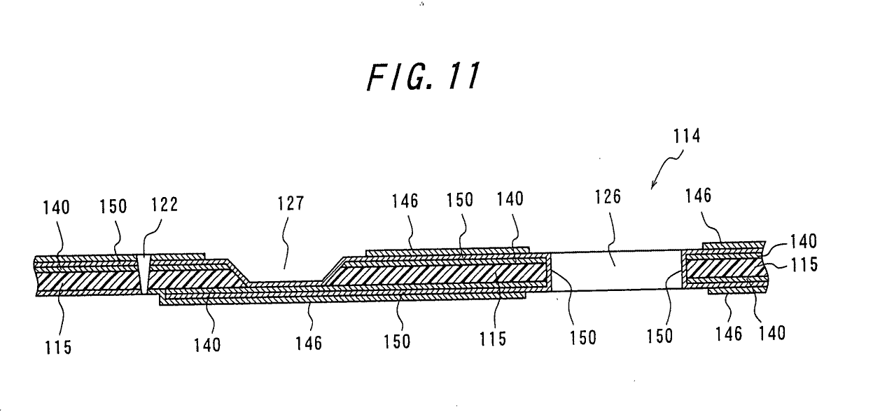

Next, the electric contact of claim 8 and claims 9-13 will be explained. A further electric contact structure according to the invention will be explained with reference to FIGS. 11 to 13.

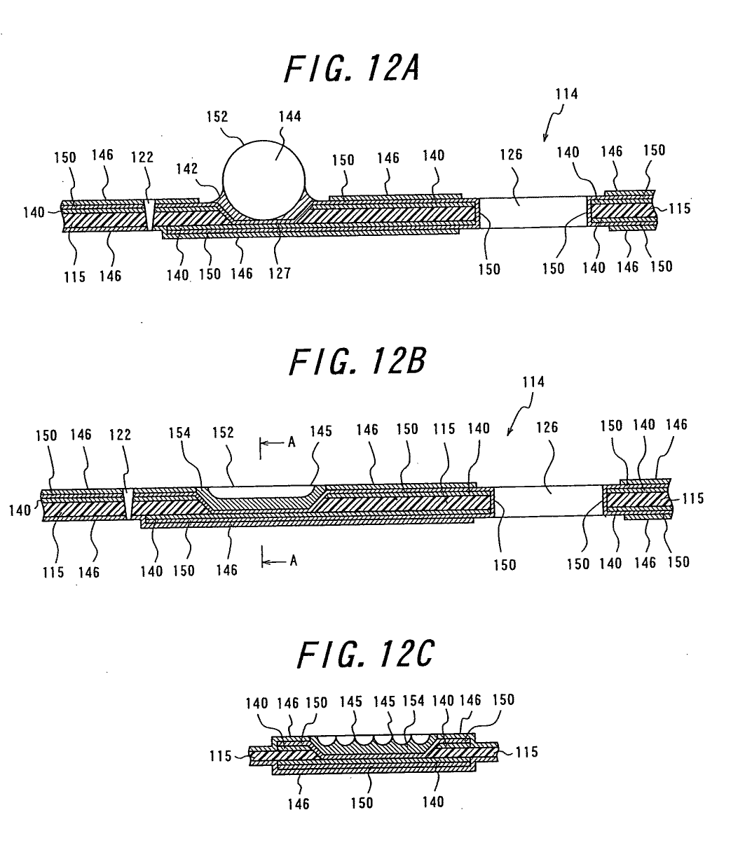

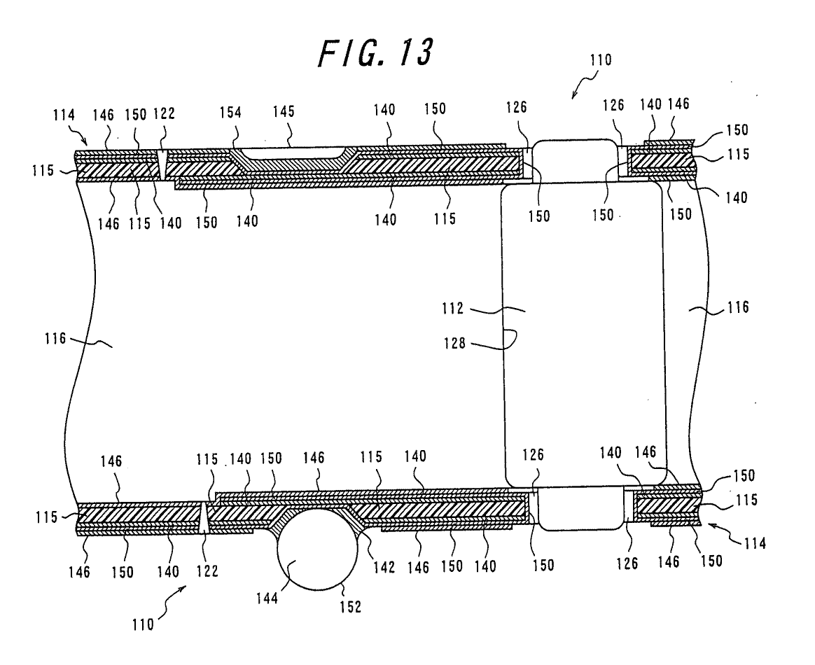

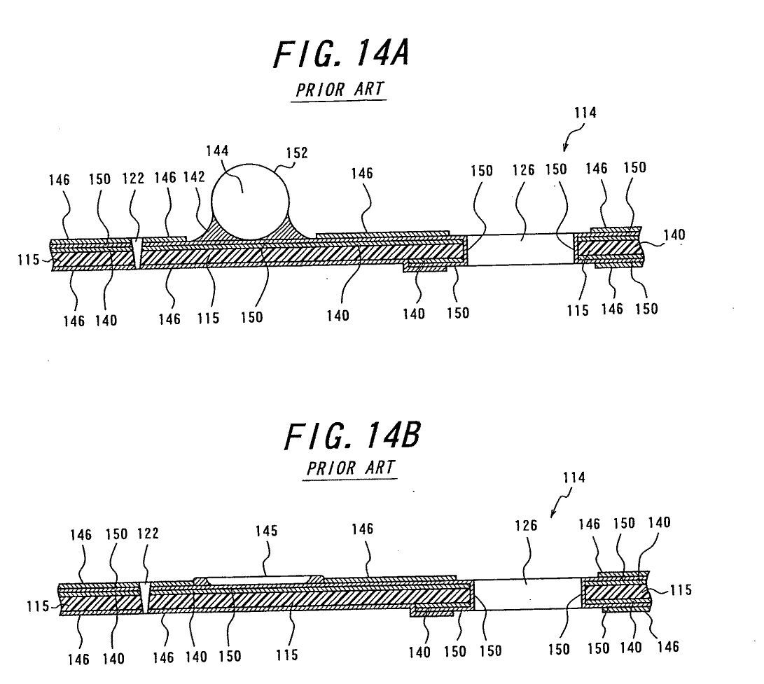

FIG. 11 is a view for explaining the electric contact structure according to the invention. FIG. 12A is a sectional view illustrating an arrangement of a metal ball arranged at a blind hole, while FIG. 12B is a sectional view showing an arrangement of a protrusion contact provided at a blind hole. FIG. 12C is a sectional view of the arrangement taken along the line A-A in FIG. 12B. FIG. 13 is a sectional view of a connector having protrusion contacts each provided at a blind hole on one surface and metal balls each arranged at a blind hole.

First, the electric contact structure will be explained referring to FIG. 11. A flexible printed circuit board 114 includes a polyimide layer 115 and copper foils 140 on both surfaces of the polyimide layer, respectively, so as to embrace the polyimide layer. The board 114 is formed with a plurality of blind holes 127 at predetermined positions by means of etching process or laser beam machining in one direction from one surface so that the copper foils 140 on the other side (rear side) are exposed at the bottoms of the blind holes 127. Simultaneously with the working of the blind holes 127, the circuit board 114 is formed with a plurality of through-holes 126. Thereafter, the circuit board 114 is plated with copper over the copper layers 140 on both the sides and insides of each of the blind holes 127 and each of the through-holes 126 to form a copper plate layer 150 so that a continuity across the copper foils 140 on both the sides is accomplished through the plated blind hole 127 and through-hole 126. Electric current can be increased by the continuity across the copper foils 140 on both the sides.

Provided in the blinded holes 127 are electric contacts so as to adapt to mating objects, respectively, thereby achieving the optimization of the electric contacts. For example, in the case that a mating object is flat, a contact provided in the blind hole 127 is the metal ball 144 extending toward the mating object as shown in FIG. 12A. If a mating object is of an extending shape, a contact is in the form of a row of mountains as the protrusion contact 145 shown in FIGS. 12B and 12C.

The electric contact using the metal ball 144 as shown in FIG. 12A will be explained. After the blind holes 127 on their insides are each coated with a metal paste layer 142 or conductive paste layer, a metal ball 144 is pushed into the blind hole, during which the metal paste layer 142 is solidified, and the metal ball 144 is fixed thereto under the condition of the metal ball in contact with the copper plate layer. Preferably the metal ball 144 is plated with a noble metal of high conductivity over at least the part adapted to contact a mating object as shown by reference numeral 152.

The electric contact as the protrusion contact 145 shown in FIG. 12B will be explained. The insides of the blind holes 127 are each plated up to the surface of the copper foil 140 to form a plate layer 154, and at least one protrusion contact 145 in the form of a row of mountains is provided on the plate layer 154. For forming the protrusion contact 145, after the blind hole 127 is plated with copper up to the surface of the copper foil 140, an etching process is performed to form the protrusion contact 145 of the shape shown in FIGS. 12B and 12C. Preferably the protrusion contact 145 is plated with a noble metal of high conductivity over at least the part adapted to contact a mating object as shown by reference numeral 152.

A cover lay 146 is arranged on the copper plate layers 150 except for the blind holes 127 and the through-holes 126. By arranging the cover lay 146, the metal balls 144 can be fixed in position by solidification of the metal paste layer in a settled and balanced manner. An opening angle of the cover lays 146 is preferably 30° to 60°. In this way, the copper plating in the blind holes 127 can be easily effected for the purpose of forming the protrusion contacts 145.

Next, the electric contact of claim 5 will be explained.

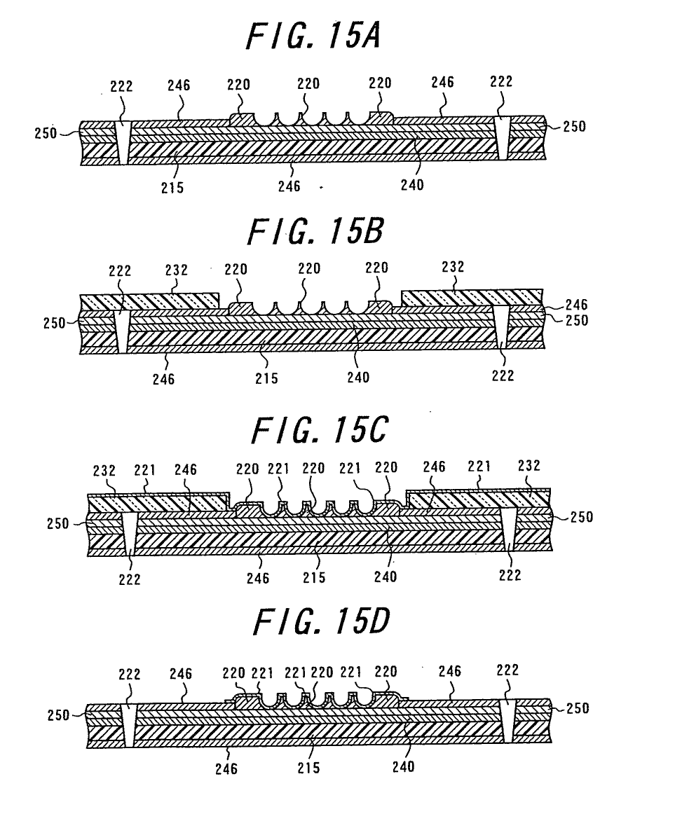

Said electric contact 220 is formed over the copper foil 240 as shown in FIG. 15A in a form to match with the contacting member and at least a portion thereof where contacting with the mating contact is applied with a hard conducting thin film 221 by a method described before as shown in FIG. 15C. Also around the periphery of the contact 220, a substantially U shape slit 222 is formed. Underneath the copper foil 240, there is provided an elastic body. By the provision of the slit 222 and the arrangement of the elastic body, when the contact 220 is in contact with the mating contact, the mating contact is able to slide over the electric contact 220.

Next, the method for producing the electric contact of claims 4 and 15 and claims 17-19 will be explained.

The configurations of the electric contacts 70 according to the invention shown in FIGS. 4A to 10D have been already explained. The methods for producing the electric contacts 70 will be explained with reference to FIGS. 7A to 7D, 8A to 8D and 10A to 10D. First, a producing method shown in FIGS. 7A to 7D will be explained.

In a first step, a copper foil 90 is coated with a metal paste layer 92 or conductive paste layer over a predetermined area shown in FIG. 7A.

In a second step, a metal ball 94 is mounted onto the metal paste layer 92 or conductive paste layer in the direction shown by an arrow A in FIG. 7B, and then the metal ball 94 is pushed to the copper foil in the direction shown by an arrow B in FIG. 7C.

In a third step, the metal ball 94 is fixed to the copper foil 90 by solidification of the metal paste layer 92 by heating it at the temperature of 160° C. shown in FIG. 7D. In a fourth step, the metal ball 94 is partly plated with gold over at least a contact portion adapted to contact a mating object.

In the method shown in FIGS. 7A to 7D by way of example, after the metal ball 94 has been fixed to the copper foil 90 by solidification of a metal paste, at least the part of the metal ball adapted to contact the mating connector is gold-plated. As an alternative, after gold-plating, the metal ball 94 may be fixed to the copper foil 90.

A producing method shown in FIGS. 8A to 8D will then be explained. In a first step, a cover lay 96 having a through-hole 98 of a predetermined size is arranged on a copper foil 90 and then a metal paste layer 92 or conductive paste layer is coated on the inside of the through-hole 98 as shown in FIG. 8A. As described above, it is of course possible to produce a number of electric contacts at a time using a cover lay having a number of through-holes.

In a second step, a metal ball 94 is mounted onto the metal paste layer 92 or conductive paste layer in the direction shown by an arrow C in FIG. 8B, and thereafter the metal ball 94 is pushed to the copper foil in the direction shown by an arrow D in FIG. 8C.

In a third step, the metal ball 94 is fixed to the copper foil 90 by solidification of the metal paste layer 92 by heating the layer 92 at the temperature of 160° C. as shown in FIG. 8D.

In a fourth step, the metal ball 94 is plated with gold over at least a contact portion adapted to contact a mating object.

In the method shown in FIGS. 8A to 8D, by way of example, after the metal ball. 94 has been fixed to the copper foil 90 by solidification of the metal paste, at least the part of the metal ball adapted to contact the mating connector is gold-plated. As an alternative, after gold-plating, the metal ball 94 may be fixed to the copper foil 90.

In connection with this method, an opening angle of the through-hole 98 of the cover lay 96 widening upwardly viewed in the drawing is preferably 30° to 70° in order to fix the metal ball 94 in position by solidification of the metal paste layer in a settled and balanced manner as shown in FIG. 4C.

Although it is sufficient to plate the metal ball 94 with gold over at least the contact portion adapted to contact a mating object as described above, it is preferable that before plating with gold, the metal ball is plated with copper (in order to securely fix the metal ball to the copper foil 90) and further plated with nickel (to improve the adherence of gold plating).

A producing method shown in FIGS. 10A to 10D will then be explained. In a first step, after a cover lay 96 having a through-hole 98 of predetermined size has been arranged on a copper foil 90, the through-hole 98 and the cover lay 96 are plated with copper to form a copper plate layer 100 reaching at least the upper surface of the cover lay 96, and the copper plate layer 100 is coated with a metal paste layer 92 or conductive paste layer as shown in FIG. 10A.

In a second step, a metal ball 94 is mounted onto the metal paste layer 92 or conductive paste layer in the direction shown by an arrow E in FIG. 10B, and thereafter the metal ball 94 is pushed to the copper foil in the direction shown by an arrow F in FIG. 10C.

In a third step, the metal ball 94 is fixed to the copper plate layer 100 by solidification of the metal paste layer 92 by heating it at the temperature of 160° C. shown in FIG. 10D.

In a fourth step, the metal ball 94 is plated with gold over at least a contact portion adapted to contact a mating object.

In the method shown in FIGS. 10A to 10D, by way of example, after the metal ball 94 has been fixed to the copper foil 90 by solidification of a metal paste, at least the part of the metal ball adapted to contact the mating connector is gold-plated. As an alternative, after gold-plating, the metal ball 94 may be fixed to the copper foil 90.

In connection with this method, an opening angle of the through-hole 98 of the cover lay 96 widening upwardly viewed in the drawing is preferably 30° to 70° in order to fix the metal ball 94 in position by solidification of the metal paste layer in a settled and balanced manner as shown in FIGS. 4C and 9.

Although it is sufficient to plate the metal ball 94 with gold over at least the contact portion adapted to contact a mating object as described above, it is preferable that before plating with gold, the metal ball is plated with copper (in order to securely fix the metal ball to the copper foil 90) and further plated with nickel (to improve the adherence of gold plating).

Next, the method for producing the electric contact of claim 16 will be explained.

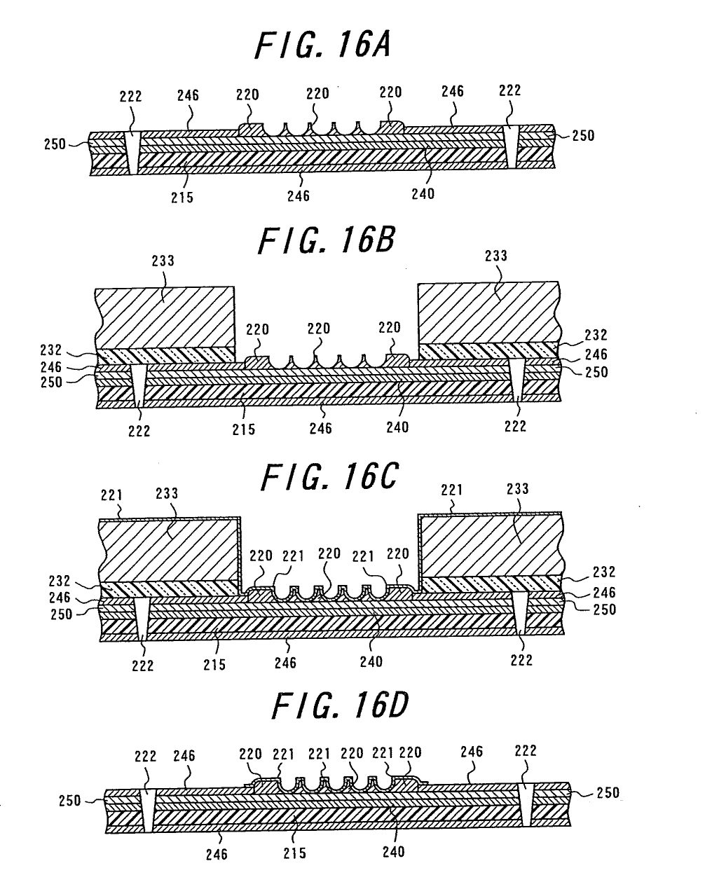

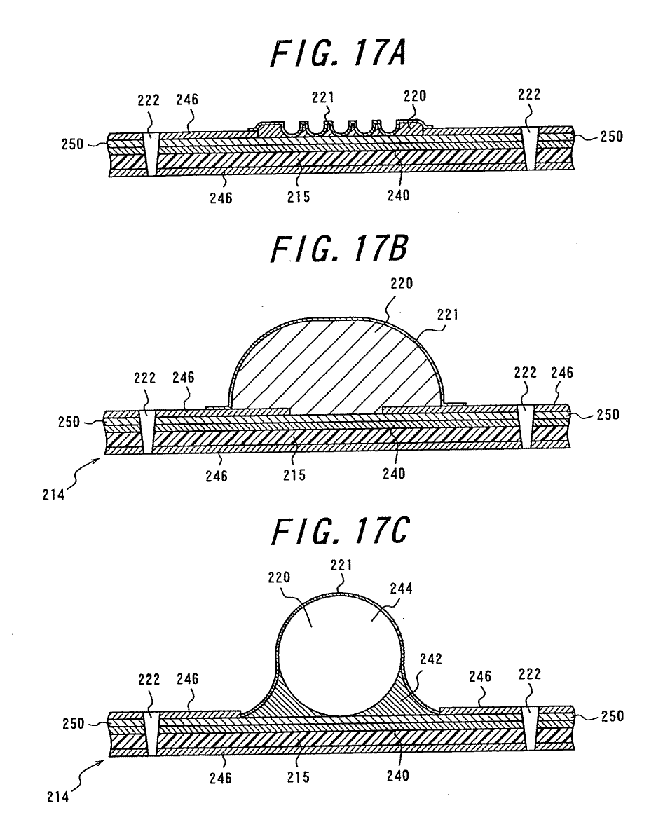

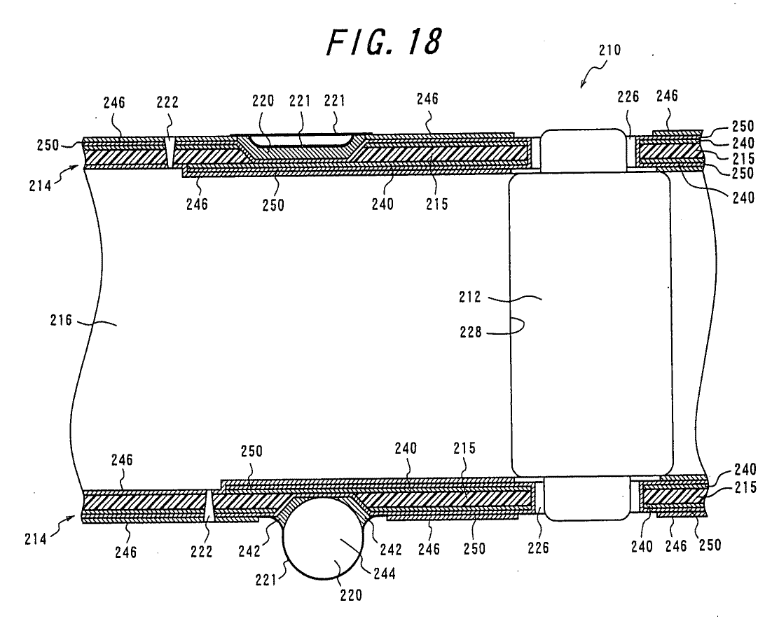

A further electric contact and a method for producing the electric contact according to the invention will be explained with reference to FIGS. 15A to 18. FIG. 15A is a partly sectional view of the electric contact, and FIG. 15B is a partly sectional view of the electric contact with dry films as protecting film members attached. FIG. 15C is a partly sectional view of the electric contact with conductive hard films blown to the state shown in FIG. 15B, while FIG. 15D is a partly sectional view of the electric contact with the dry films as protecting film members removed. FIG. 16A is a partly sectional view of an electric contact, and FIG. 16B is a partly sectional view of the elastic contact with dry films and stainless steel as protecting film members. FIGS. 16C is a partly sectional view of the electric contact with conductive hard films blown to the state in FIG. 16B, and FIG. 16D is a partly sectional view of the electric contact with the dry films and stainless steel as protecting films removed. FIGS. 17A to 17C are views for explaining shapes of the electric contacts. FIG. 18 is a sectional view of an electrical connector using the above electric contacts.

Before explaining the method for producing the electric contacts 220, shapes of the electric contacts 220 will be explained. The electric contact 220 is formed on a copper foil 240, and there are various shapes of the electric contacts to be adapted to shapes of mating objects to contact them as shown in FIGS. 17A to 17C. For example, there are protrusion contacts in the form of a row of mountains 220 as shown in FIG. 17A, contacts of a dome shape shown in FIG. 17B, and contacts of a ball shape extending in the form of a sphere using a metal ball 244 shown in FIG. 17C. Other than them, there are also flat contacts not shown.

A method for producing the electric contact 220 will then be explained by referring to FIG. 15A. The electric contact 220 in the description has a shape of the row of mountains. The electric contact 220 of the shape shown in FIG. 15A can be produced by various methods.

In this embodiment, as shown in FIG. 15B a dry film as a protecting film member 232 is attached to or arranged on a circuit board so that at least contact portions of the electric contacts 220 adapted to contact mating objects are exposed.

Thereafter, as shown in FIG. 15C a conductive hard film 221 is formed on the whole surfaces of the state shown in FIG. 15B.

Finally, as shown in FIG. 15D, the dry film as the protecting film member 232 is removed. By removing the dry film, conductive hard films 221 are provided on at least the contacting portions to contact the mating object. The conductive hard film 221 is a coating which contains carbon and other conductive materials and is superior in conductivity and wear-resistance.

The protecting film member 232 will be explained hereafter. The protecting film member 232 serves to prevent the conductive hard film 221 from being applied to portions where application of the hard film 221 is undesirable. In order to forming the protecting film member 232, the following methods are envisioned.

1. After the dry film 232 has been attached, the dry film 232 is exposed and developed to form apertures at locations corresponding to the portions where the conductive hard films 221 should be applied.

2. A dry film 232 is attached which originally has apertures at locations corresponding to the portions where the conductive hard films 221 should be applied.

3. The portions other than that where the conductive hard films 221 should be applied are covered by a mask by printing.

4. In addition to the procedures of the above items 1 to 3, a thin stainless steel plate originally having apertures is placed.

A method for applying a conductive hard film 221 after a thin stainless steel plate 233 has been further arranged on a dry film 232 will then be explained by referring to FIGS. 16A to 16D. Explaining the differences from those of FIGS. 15A to 15D only, after a dry film 232 as a protecting film member has been attached or arranged, a thin stainless steel plate 233 having holes previously formed is located thereon. Then, a conductive hard film 221 is sprayed over the whole surfaces, and thereafter the dry film 232 and the stainless steel plate 233 are removed. A connector using such electric contacts will be explained later with reference to FIG. 18.

The electric contact 220 is not only formed on the copper foil 240 in a shape adapted to the shape of a mating object, but also provided with a conductive hard film 221 over at least contact portion adapted to contact the mating object. Moreover, the circuit board is formed with a U-shaped slit 222 around each of the electric contacts 220, and the elastomer is arranged under the copper foils 240. By providing said slit 222 and the elastomer, the mating object can slidably move on the electric contact 220 when it contacts the mating object, which will be explained in more detail later.

Next, the structure for vertically holding conductors of claims 20-23 will be explained.

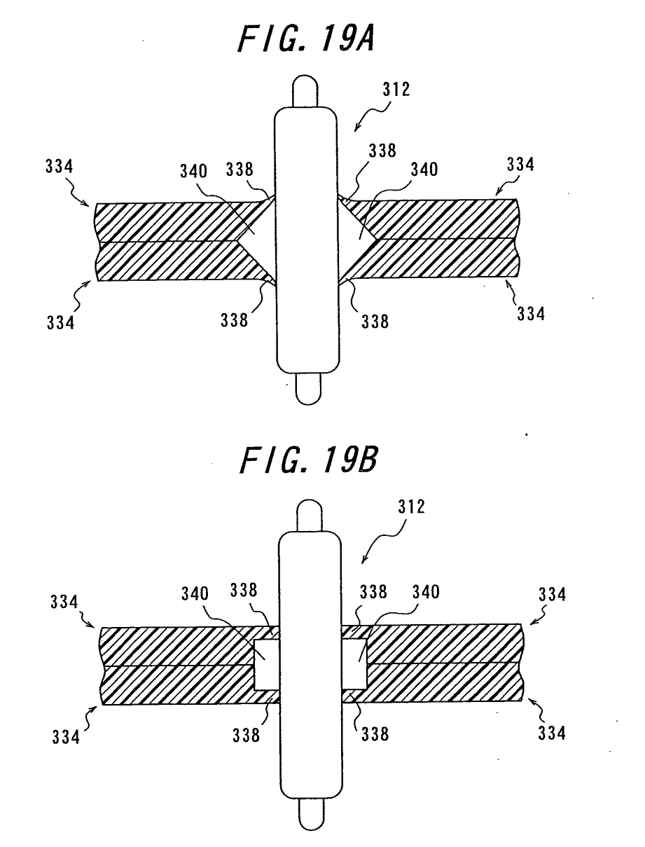

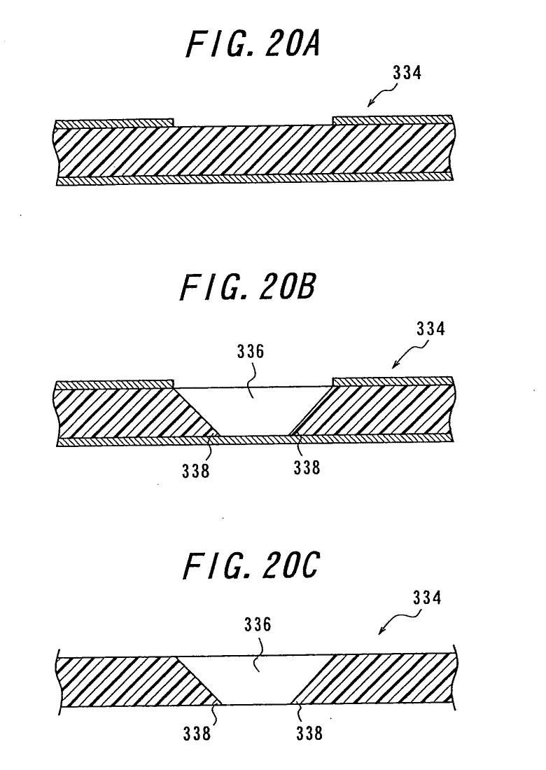

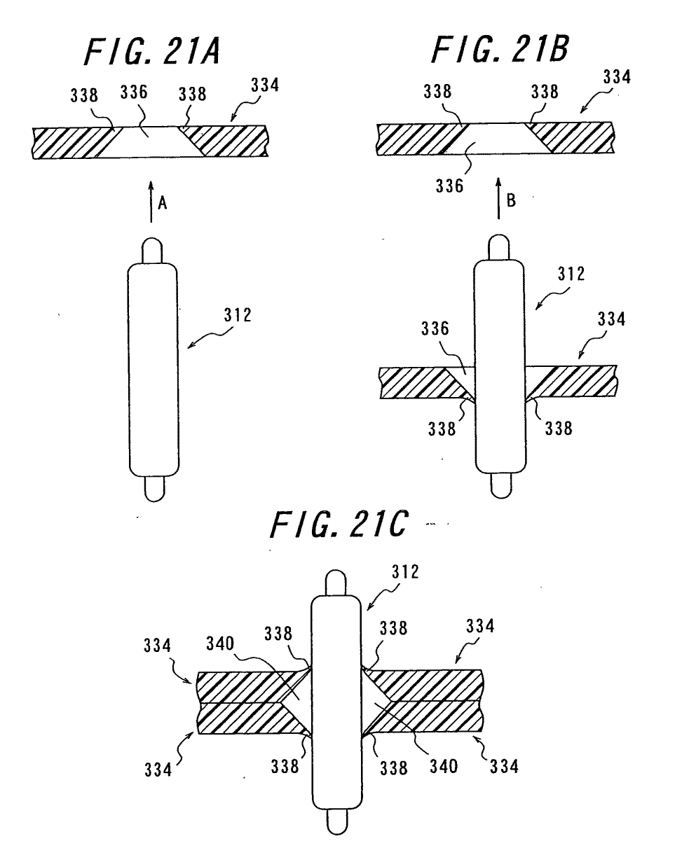

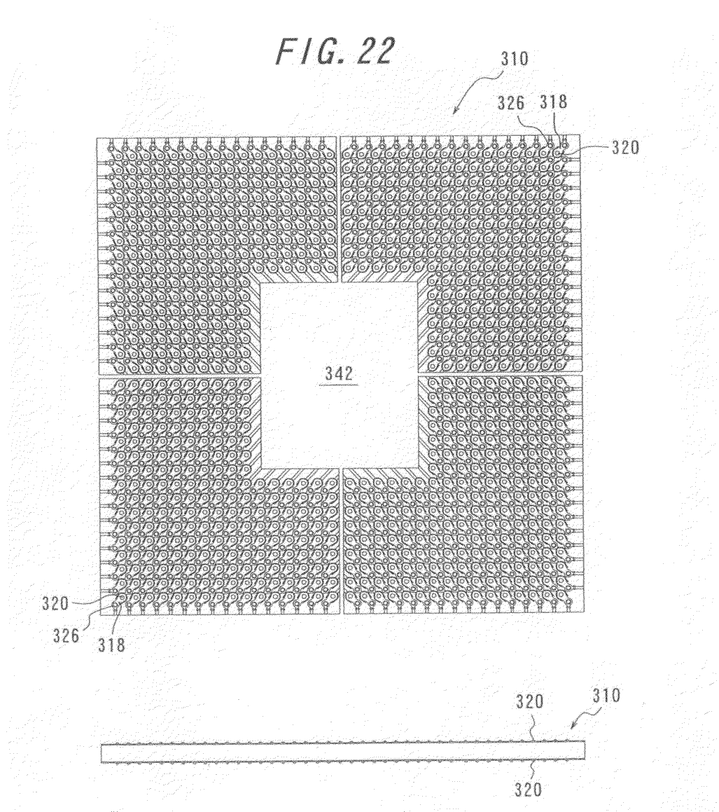

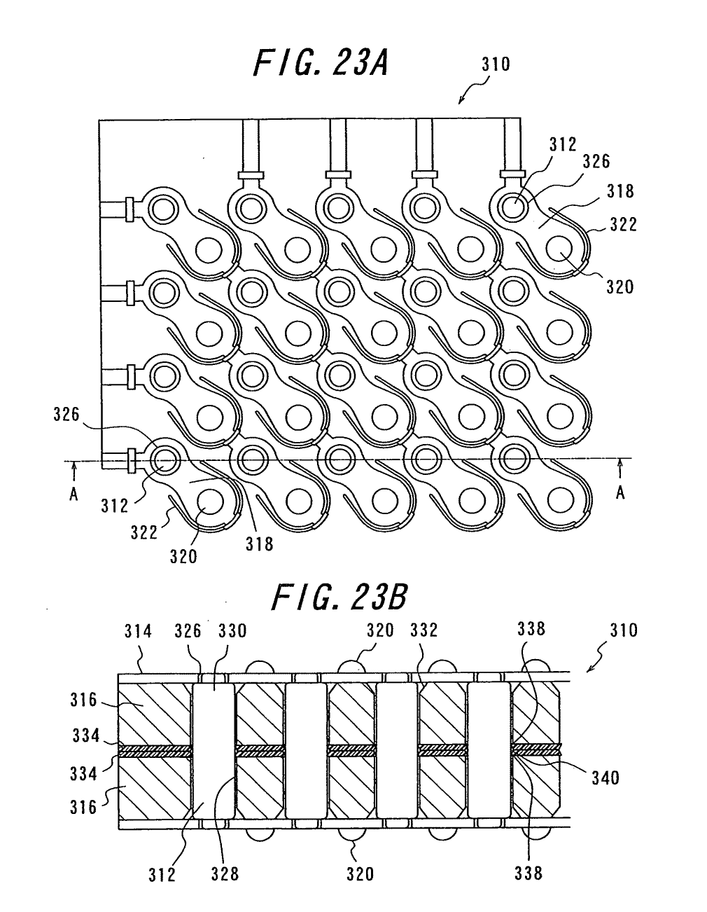

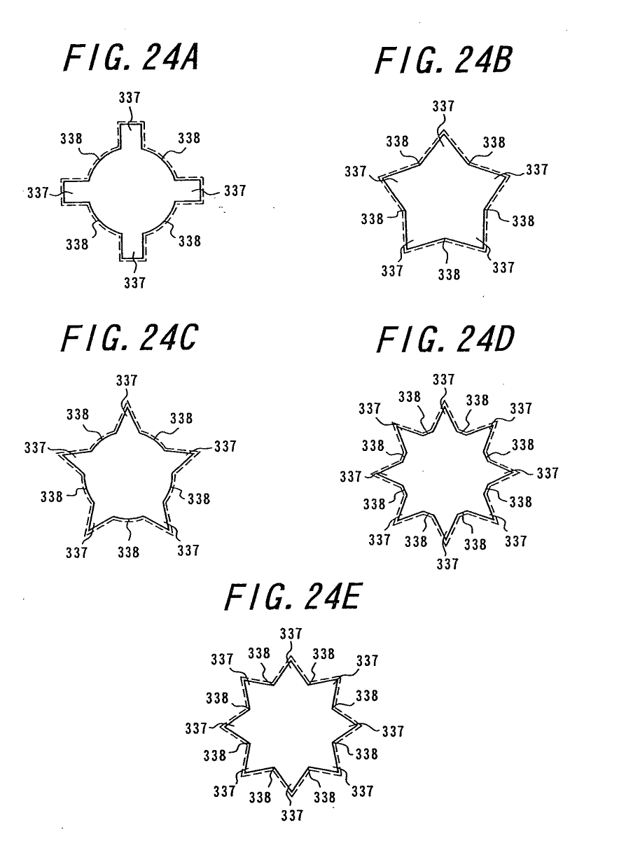

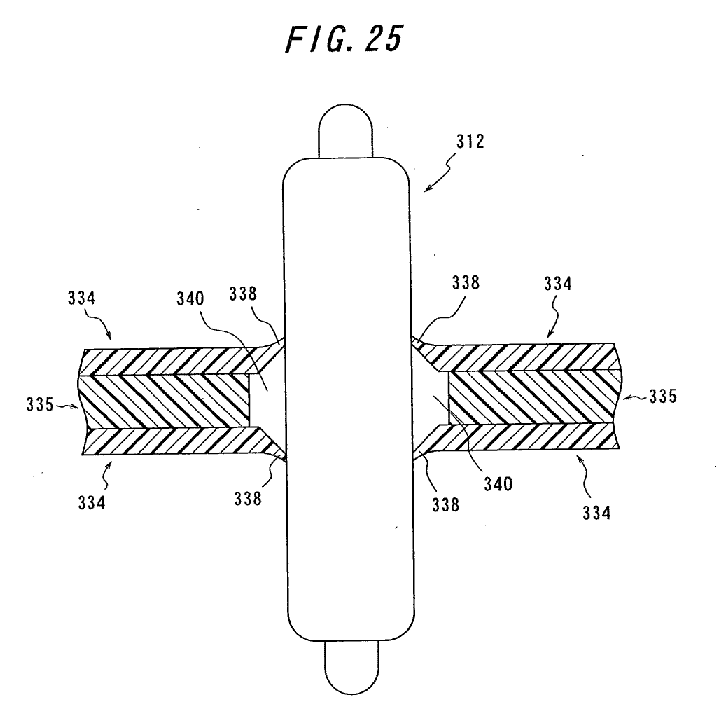

A structure for vertically holding conductors, and a method for producing plastic sheets for use in the structure according to the invention will be explained with reference to FIGS. 19A to 25. A connector using these plastic sheets will be explained later. FIG. 19A is a view illustrating a structure for vertically holding a conductor by two plastic sheets according to the invention, and FIG. 19B is a view showing a structure with protrusions slightly modified. FIGS. 20A to 20C are views for explaining the method for producing the plastic sheet. FIGS. 21A to 21C are views for explaining the method for assembling two plastic sheets and conductors to be vertically held. FIG. 22 includes a plan and a cross-sectional view of a connector using the plastic sheets. FIG. 23A is a partly enlarged plan view of the connector, and FIG. 23B is an enlarged cross-sectional view of the connector taken along the line A-A in FIG. 23A. FIGS. 24A to 22E are views for explaining shapes of notches. FIG. 25 is a view of an arrangement with a spacer between two plastic sheets to enlarge supporting length for a conductor vertically held.

The method for producing plastic sheets 334 will be explained by referring to FIGS. 20A to 20C. First, as shown in FIG. 20A an alkali resistant mask is applied to either of surfaces of a plastic sheet 334 for forming conductor inserting holes in the plastic sheet, and a further alkali resistant mask is applied to the whole other surface of the plastic sheet for the purpose of masking the portions of the plastic sheet not forming inserting holes.

Second, as shown in FIG. 20B, the surface of the plastic sheet from which the forming the conductor inserting holes should be started is processed by alkali etching to form the inserting holes 336 passing through the plastic sheet 334. In forming the inserting holes 336, each of the holes 336 is tapered to the other surface of the plastic sheet to make smaller the diameter of the hole at the other surface so that a projection 338 circumferentially extends on the inner wall of the hole on the side of the other surface. In the case that particularly the inner diameter of the projections 338 is 1 mm or less, the projections 338 and notches 337 (FIGS. 24A to 24E) are preferably formed by etching. The notches 337 will be explained in more detail later with reference to FIGS. 24A to 24E.

The structure for vertically holding the conductors 312 according to the invention will then be explained by referring to FIGS. 19A and 19B. As shown in FIG. 19A and 19B, each of the plastic sheets 334 is formed with a plurality of inserting holes 336 for a plurality of conductors 312 to form the projection 338 circumferentially extending on the inner wall of each of holes 336 on the side of either surface of the plastic sheet 334. Two plastic sheets 334 thus processed are superimposed in an aligned relationship so that the opposite inserting holes 336 of the two superimposed plastic sheets are aligned with each other and the projections 338 are positioned on the sides of the outer surfaces of the two plastic sheets to form recesses 340 each consisting of two opposite inserting holes 336. In this manner, each of the conductors 312 is held by two projections 338 in two inserting holes.

The sizes of the inserting holes 336 and the projections 338 may be suitably designed depending upon sizes of the conductors 312 so that each of the conductors 312 is held by the projections 338 on both the sides of the recess 340. The inner diameter of the projections 338 is approximately 0.01 to 0.03 mm less than the outer diameter of the conductors 312 in the illustrated embodiment.

In assembling the plastic sheets 334 and conductors 312, as shown in FIGS. 21A to 21C first a conductor 312 is inserted with its one end into the inserting hole 336 of one plastic sheet 334 from the side of the plastic sheet opposite from the projection 338. Then the conductor 312 is inserted with the other end into the inserting hole 336 of the other plastic sheet 334 from the side of the plastic sheet opposite from the projection 338. In this manner, all the conductors 312 are inserted into the inserting holes 336 of both the plastic sheets 334. Thereafter the two plastic sheets 334 are moved toward and contacted to each other under a condition that all the conductors are subjected to tensile forces. In this way, the conductors passing through the two plastic sheets are supported by the two projections 338 on the inner walls of the holes 336 at both ends, respectively.

In the structure of the invention for vertically holding conductors 312, a mask capable of forming the predetermined inserting holes in the plastic sheet is applied to either of the surfaces of a plastic sheet 334, and a mask is applied to the whole other surface of the plastic sheet. Thereafter, the etching process is applied to form the inserting holes 336 in the plastic sheet 334 in a manner that the respective holes 336 each include the projection 338 circumferentially extending on the inner wall on the side of the surface of the plastic sheet 334 to which the overall masking has been applied. Two plastic sheets thus formed with the conductor inserting holes 336 are attached to each other such that the projections 338 are situated on the sides of the outer surfaces of the two attached plastic sheets 334.

Shapes of notches 337 formed in each of the projections 338 circumferentially extending on the inner wall of the inserting hole 336 on its one side will be explained with reference to FIGS. 24A to 24E. The notches 337 serve to prevent the plastic sheet 334 from being deformed even if the inserting holes 336 are arranged with a narrow pitch (conductors 312 being arranged with the narrow pitch) and the number of the conductors increases. In other words, when the conductors 312 are supported in the inserting holes 336 of the plastic sheets 334, spreading stresses acting upon the projections 338 by the conductors 312 are dispersed by the notches 337. For this purpose, at least two notches 337 are required in each of the projections 338.

In FIG. 24A, four notches are provided and spaced 90° apart, and in FIGS. 24B and 24C, five notches are spaced at an interval of 72°. In FIGS. 24D and 24E, eight notches are spaced at an interval of 45°. In FIGS. 24B and 24E, projections (holding portions) 338 are adapted to contact the respective conductor with points (theoretically point to point contact), while in FIGS. 24C and 24D, projections (holding portions) 338 adapted to contact the respective conductor with surfaces (theoretically surface to surface contact). In the embodiment, the shapes of the notches 337 are substantially rectangular as shown in FIG. 24A, or substantially triangular as shown in FIGS. 22B to 22E, and any shapes may be used insofar as they do not contact the conductor 334. The sizes of the notches 337 may also be of any ones so long as they do not contact the conductor 312. However, the sizes and shapes of the notches 337 may be suitably designed in consideration of their function, pitches of the conductors 312 (inserting holes 336), strength of the plastic sheets 334 depending upon the pitches of the holes and the like. The diameter (X) of the conductors 312, the inner diameter (Y) of the projections 338 of the inserting holes 336, and diametrically opposed distance (Z) of the notches 337 are in a relation of Y<X<Z. In the embodiment, Y is 386 μm, X is 400 μm and Z is 410 μm.

An assembling method for vertically holding conductors 312 by two plastic sheets 334 will then be explained with reference to FIGS. 21A to 21C. First, as shown in FIG. 21A one conductor 312 is inserted with its one end into the inserting hole 336 of the plastic sheet 334 in the direction shown by an arrow A from the opposite side from the projection 338.

Second, as shown in FIG. 21B the conductor 312 is inserted with the other end into the inserting hole 336 of the other plastic sheet 334 in the direction shown by an arrow B from the opposite side from the projection 338. By the above first and second steps, the conductor 312 is held by the projections 338 positioned on the sides of the outer surfaces of the superimposed plastic sheets 334. Needless to say, these two steps are simultaneously carried out for all the conductors 312 before the two plastic sheets are superimposed.

In the case complying with a requirement for vertically supporting the conductors 312 with even higher accuracy, the thickness of the plastic sheets is required to be increased so that the distance between the two projections 338 supporting one conductor is increased. In that case, if the thickness of the plastic sheets is merely increased, the processing time of etching for forming the inserting holes 336 is elongated to increase the manufacturing cost, and at the same time the variation in inner diameter of the projections 338 of the inserting holes 336 for holding conductors 312 may increase so that the holding forces for the conductors 312 would vary in a wider range, whereby the vertically holding accuracy for conductors 312 will be lowered. To solve this problem, a spacer 335 having a required thickness is arranged between the two plastic sheets 334 (FIG. 25). The thickness of the spacer 335 may be suitably designed in consideration of the required accuracy of vertically held conductors 312 and required overall thickness of the plastic sheets 334. The spacer 335 may be suitably designed so that inner walls of holes 340 of the spacer 335 for receiving the conductors 312 do not contact the conductors 312 and suitably correspond to the inserting holes 336 of the plastic sheets 334.

The plastic sheets 334 will then be explained. The plastic sheets 334 are produced as described above and formed from an electrically insulating plastic material by means of the injection molding of the known technique. The materials suitable for the plastic sheets 334 may be suitably selected in consideration of dimensional stability, workability, manufacturing cost and the like and generally include polybutylene terephthalate (PBT), polyamide (66PA or 46PA), liquid crystal polymer (LCP), polycarbonate (PC) and the like and combination thereof.

In this way, one plastic sheet 334 is formed with a plurality of inserting holes 336 each which receives a conductor 312 and is provided therewithin with the projection 338 circumferentially extending on the inner wall of the inserting hole 336 on the side of one surface of the sheet. Two plastic sheets thus formed with the inserting holes 336 are superimposed in an aligned relationship so that the projections 338 are situated on the sides of the outer surfaces of the two superimposed plastic sheets 334 to form a recess in each of the two opposite inserting holes 336, thereby holding the conductors 312 by the projections 338 in the two opposite inserting holes 336 on both sides thereof, respectively.

It is desirable to provide at least two notches 337 in each of the projections 338 circumferentially extending on the inner wall of the inserting hole 336 on its one side. Moreover, it is desirable to arrange a spacer 335 having a required thickness between the two superimposed plastic sheets 334 in the case that increased overall thickness of the superimposed plastic sheets 334 is desired, depending upon required accuracy of vertically held conductors 312 and required overall thickness of the two plastic sheets 334.

Next, the laser beam machining method of claims 24-27 will be explained.

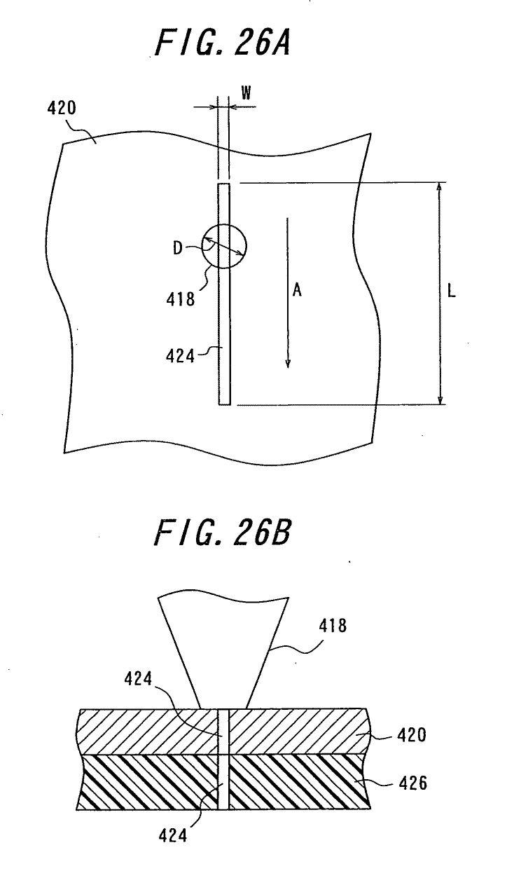

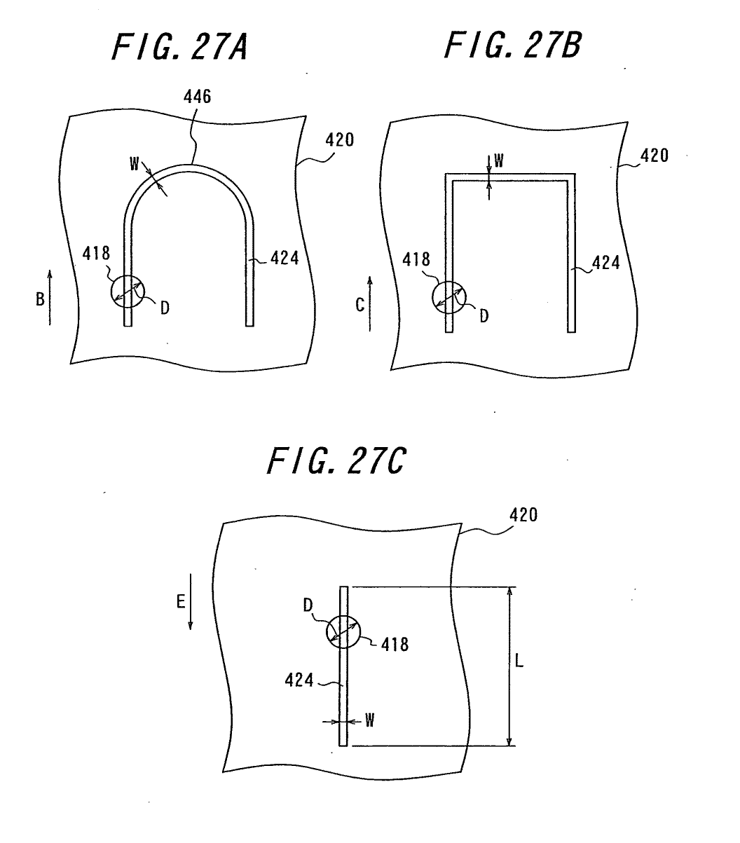

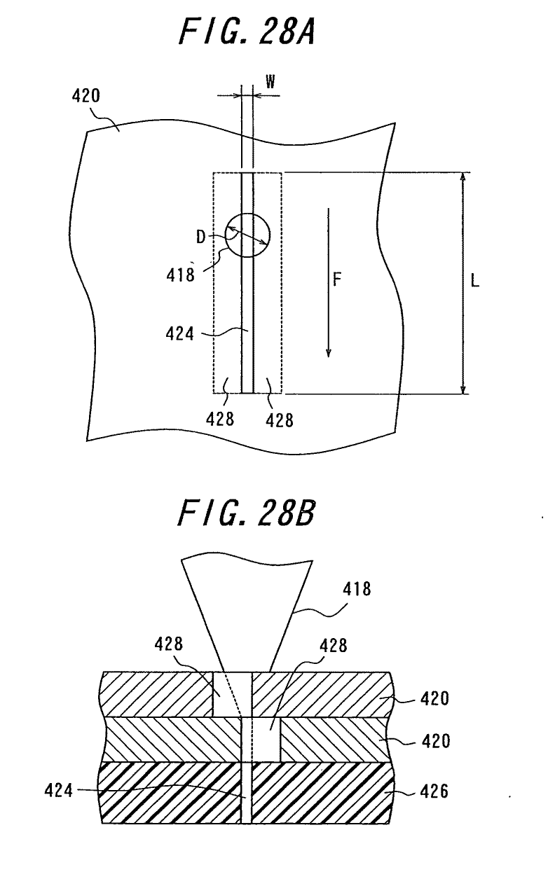

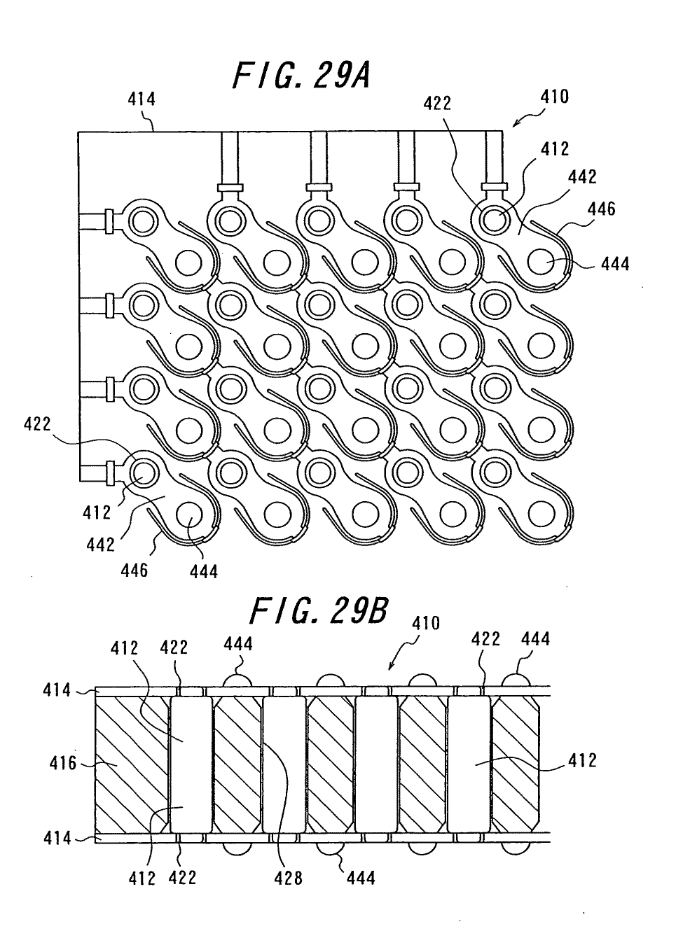

A laser beam machining method according to the invention will then be explained with reference to FIGS. 26A to 29B. FIG. 26A is a plan view for explaining a state that a laser beam impinges against a workpiece, and FIG. 26B is a sectional view of the part on which the laser beam has impinged. FIGS. 27A to 27C are views for explaining shapes to be machined by the laser beam. FIG. 28A is a plan view of a state at a moment when the laser beam impinges onto a workpiece using a masking different from that in FIG. 26A. FIG. 28B is a sectional view of the part onto which the laser beam has impinged onto the workpiece shown in FIG. 28A. FIG. 29A is a partly enlarged plan view of an electrical connector having slits formed by the laser beam machining method described above, while FIG. 29B is a partly enlarged cross-sectional view of the electrical connector shown in FIG. 29A.

Before explaining the laser beam machining according to the invention, the shapes to be machined will be explained by referring to FIGS. 27A to 27C. The machining method according to the invention is suitable for machining a through-groove or slit having a dimensional relation of “W<D<L”, where W is a width of the slit 424, L is a length of it, and D is a converged or focused laser beam diameter. In other words, this machining is suitable in the case that the width W of a through-groove or slit 424 to be machined is smaller than the focused laser beam diameter D, and the length L of the through-groove of slit 424 to be machined is larger than the focused diameter D of the laser beam 418.

So long as through-slits 424 to be machined are in the above relation, any shapes may be machined such as, for example, a substantially U-shape as shown in FIG. 27A, a substantially U-shape having sharp corners as shown in FIG. 27B and a straight shape as shown in FIG. 27C. The laser beam 418 advances along the slits 424 in directions shown by arrows B, C and E shown in FIGS. 27A to 27C.

The laser beam machining method according to the invention will be explained by referring to FIGS. 26A and 26B. First, arranged on a workpiece 426 to be formed with a through-groove or slit 424 is a thin stainless steel plate 420 having a through-slit 424 having a width W smaller than and a length L larger than the focused laser beam diameter D.

Second, the laser beam 418 is moved along the through-slit 424 of the stainless steel plate 420 in the direction shown by an arrow A in FIG. 26A to machine a through-groove or slit. The size of the stainless steel plate 420 may be suitably designed to adapt to the size of the workpiece 426. The thickness of the stainless steel plate 420 may be determined not to be deformed upon the laser beam being applied, and is 0.05 to 0.5 mm in the illustrated embodiment.

The focused laser beam diameter D to be used is preferably 40 μm. Carbon dioxide laser and YAG high frequency laser as the laser beam 418 may be preferable to be used. The use of the carbon dioxide laser and the YAG high frequency laser achieves a low cost machining.

A laser beam machining using a masking method other than that described above will be described with reference to FIGS. 28A and 28B. Arranged on a workpiece 426 to be formed with a through-slit 424 are two thin stainless steel plates 420 each having a slit 428 so that the slits 428 of the two stainless steel plates 420 are slightly shifted to each other. As shown in FIGS. 28A and 28B, the two stainless steel plates 420 are thus arranged so that the slits 428 of the two stainless steel plates 420 are partly overlapping with or shifted to each other to form a slit of a narrower width, thereby enabling the workpiece to be formed with a through-slit 424 having a width W less than and a length L larger than the focused laser beam diameter D. The size of the slits 428 of the stainless steel plates may be any ones insofar as the workpiece can be formed with a through-slit 424 having a width W less than and a length L larger than the focused laser beam diameter D by arranging the stainless steel plates to cause their slits to be shifted to each other. The width of the slits of the stainless steel plates is 0.05 mm in the illustrated embodiment.

Thereafter, the laser beam 418 is moved along the partly overlapped portion 424 of the slits 428 of the two thin stainless steel plates 420 in the direction shown by an arrow F in FIG. 28A, thereby performing the machining of the through-slit. The size of the stainless steel plates 420 may be suitably designed to be adapted to the workpiece 426 to be machined. The thickness of the stainless steel plates 420 may be designed so as not to be deformed by the laser beam 418, and is 0.05 to 0.5 mm in the illustrated embodiment.

Next, the connector using the perpendicular maintenance structure of the plastic sheet of claims 29-31 will be explained.

Returning to FIGS. 19A to 25, a connector 310 using the plastic sheets 334 having the configuration described above and produced by the producing method described above by referring to FIGS. 19A to 20C will be explained. The connector 310 according to one embodiment at least comprises elastomers 316, conductors 312, flexible printed circuit boards 314, and plastic sheets 334.

In producing the connector 310, a plurality of conductors 312 are inserted with their one end into the inserting holes 336 of the one plastic sheet 334 from the side opposite from the side provided with the projections 338, respectively, and the conductors 312 are inserted with their other end into the inserting holes 336 of the other plastic sheet 334 from the side opposite from the side provided with the projections 338, respectively, so that the two plastic sheets 334 are superimposed in an aligned relationship in a manner that the projections 338 are located on the sides of the outer surfaces of the two superimposed plastic sheets 334, thereby supporting the conductors 312 by two projections 338 in the opposite inserting holes 336 of the two plastic sheets, respectively. Thereafter, two elastomers 316 having holes through which the conductors 312 can be passed are provided on both the surfaces of the two superimposed plastic layers 334, or one elastomer 316 having the holes is provided on either of the surfaces of the plastic sheets 334. Then, one or two flexible printed circuit boards 314 are arranged on either or both the sides of the elastomers 316. The flexible printed circuit board 314 has through-holes 326 for receiving the conductors 312 and contacts 320 adapted to contact mating objects, and the flexible printed circuit board 314 is connected to the conductors 312.

The electric contacts 320 are each adapted to contact a mating object and formed of an extending metal ball on a copper foil or by plating a copper foil with a metal (FIGS. 22 and 23A and 23B).

As shown in FIGS. 22 and 23A, the flexible printed circuit board 314 is provided with a plurality of electric contact elements 318 at locations corresponding to contacts of a mating connector. The electric contact elements 318 are each provided with an electric contact 320 which is hemispherical so as to be compatible with the shape of the mating contact to facilitate the contact therebetween. The flexible printed circuit board 314 is provided with a recess or through-groove (including through-hole) as reliefs for capacitors, IC chips, resistances and the like extending higher than the contacts of the mating connector at a location within the center area corresponding to these members. The size of the recess or through-groove may be designed so as to avoid any touch with the capacitors, IC chips, resistances and the like, and may be suitably designed in consideration of a miniaturization of the connector, positional accuracy and the like.

The flexible printed circuit board 314 is formed with a substantially U-shaped slit 322 about each of the electric contact elements 318. Upon contacting a contact of a mating connector, the U-shaped slit 322 serves to cause the electric contact element 318 of the connector 310 to slidably move with the aid of the elasticity of the elastomer 316. In more detail, when the electric contact element 318 contacts a contact of the mating connector so as to be pressed by the contact, the slit 322 permits the electric contact element 318 to be deformed in a cantilevered manner as the elasticity of the elastomer 316 arranged under the circuit board permits the deformation of the electric contact element 318. Since the electric contact element 318 is deformed in the cantilevered manner, the mating contact and the electric contact element 318 will be slidably moved relative to each other. The size of the slits 322 may be suitably designed in consideration of such a function and the miniaturization of the connector 310. The electric contact element 318 is connected through its conductive portion to the through-hole 326 which is in turn connected to the conductor 312 as shown in FIGS. 23A and 23B. The size of the through-holes 326 may be suitably designed so as to receive the conductors 312 and enable the connection by soldering or the like and in consideration of the miniaturization of the connector 310, strength of the conductors 312 and capability of connection.

The conductors 312 will then be explained. The conductor 312 is substantially cylindrical and a stepped shape having a thin diameter at both ends and a thick diameter at its center. The conductor 312 is made of a metal by cutting a rod of a metal superior in conductivity, for example, brass into a predetermined length and machining the both end portions to a smaller diameter. The both end portions are to be inserted in the through-holes 326 and therefore the diameter of the both end portions may be suitably designed so that the both end portions are received in the through-holes 326 and connected thereto by soldering. The center portion of the conductor 312 is to be embedded in the elastomers 316 and therefore the diameter of the center portion may be suitably designed in consideration of the miniaturization of the connector 310, narrowed pitches and conductivity. The respective lengths of the portions of the conductor may be suitably designed in consideration of the thicknesses of the flexible printed circuit boards 314 and the elastomers 316.

The elastomers 316 as elastic bodies will then be explained. The elastomer 316 is formed with fitting holes 328 for inserting the conductors 312 thiereinto, respectively. The diameter of the fitting holes 328 may be suitably designed so as to permit the conductors 312 to be inserted into the fitting holes 328 and in consideration of holding force for the conductors 312 and the like. The diameter of the fitting holes 328 is approximately 0.02 mm smaller than the diameter of the center portions of the conductors 312 in the embodiment. The elastomer 316 is preferably formed with a recess 332 at each of ends of the fitting holes 328 for preventing warp of the elastomer 316 caused by part of the elastomer unexpectedly extending on a shoulder of the conductor 312. The elastomers 316 are formed from silicon rubber or fluororubber.

A connector using flexible printed circuit boards having through-holes 22 formed by the method explained by referring to FIGS. 1A to 1H will then be explained with reference to FIGS. 2 to 3B. As shown in FIG. 2, fine conductors 12 are inserted into the through-holes 22 formed by the steps shown in FIGS. 1A to 1H and connected to the through-holes 22 formed in patterns, thereby forming a connector 10 to be used.

As shown in FIGS. 3A and 3B, such a connector 10 comprises at least an elstomer 16, fine conductors 12 and flexible printed circuit boards 14.

The configuration of the electric contacts will be explained. The electric contacts are each adapted to contact a mating object and formed by a metal ball on a copper foil or by plating a copper foil with a metal so as to extend from the copper foil.

The flexible printed circuit board 14 will be explained. The flexible printed circuit board 14 is provided with a plurality of electric contact elements 42 at locations corresponding to contacts of a mating connector. The electric contact elements 42 are each provided with an electric contact 44 which is hemispherical so as to be compatible with the shape of the mating contact to facilitate the contact therebetween.

The flexible printed circuit board 14 is formed with a substantially U-shaped slit 46 about each of the electric contact elements 42. Upon contacting a contact of a mating connector, the U-shaped slit 46 serves to cause the electric contact element 42 of the connector 10 to slidably move with the aid of the elasticity of the elastomer 16. The reason of the sliding movement is already described. The size of the slits 46 may be suitably designed in consideration of such a function and the miniaturization of the connector 10. The electric contact element 42 is connected through its conductive portion to the through-hole 22 as shown in FIGS. 1A to 1H which is connected to the fine conductor 12. The size of the through-holes 22 may be suitably designed so as to receive the fine conductors 12 and enable the connection by soldering or the like and in consideration of the miniaturization of the connector 10, strength of the fine conductors 12 and capability of connection.

The fine conductors 12 will then be explained. The fine conductor 12 is substantially cylindrical and a stepped shape having a thin diameter at both ends and a thick diameter at its center. The fine conductor 12 is made of a metal by cutting a rod of a metal superior in conductivity, for example, brass into a predetermined length and machining the both end portions to a smaller diameter. The both end portions are to be inserted in the through-holes 22 and therefore the diameter of the both end portions may be suitably designed so that the both end portions are received in the through-holes 22 and connected thereto by soldering. The center portion of the fine conductor 12 is to be embedded in the elastomers 16 and therefore the diameter of the center portion may be suitably designed in consideration of the miniaturization of the connector 10, narrowed pitches and conductivity. The respective lengths of the portions of the fine conductors may be suitably designed in consideration of the thicknesses of the flexible printed circuit boards 14 and the elastomer 16.

The elastomers 16 will then be explained. The elastomer 16 is formed with inserting holes for inserting the fine conductors 12 thiereinto, respectively. The diameter of the inserting holes may be suitably designed so as to permit the fine conductors 12 to be inserted into the inserting holes and in consideration of holding force for the fine conductors 12 and the like. The diameter of the inserting holes is approximately 20 μm smaller than the diameter of the center portions of the fine conductors 12 in the embodiment. The elastomer 16 is preferably formed with a recess at each of ends of the inserting holes for preventing warp of the elastomer 316 caused by part of the elastomer unexpectedly extending on a shoulder of the fine conductor 12. The elastomers 16 are formed from silicon rubber or fluororubber.

A connector 60 shown in FIGS. 5 and 6 will be explained. The connector 60 uses the electric contacts 70 explained by referring to FIGS. 4A to 10D and also comprises at least an elastmer 66, fine conductors 62 and flexible printed circuit boards 64.

The flexible printed circuit board 64 is provided with a plurality of electric contact elements 68 at locations corresponding to contacts of a mating connector. The electric contact elements 68 are each provided with an electric contact 70 which is hemispherical so as to be compatible with the shape of the mating contact to facilitate the contact therebetween. The flexible printed circuit board 64 is provided with a recess or through-groove (including through-hole) as reliefs for capacitors, IC chips, resistances and the like extending higher than the contacts of the mating connector at a location within the center area corresponding to these members. The size of the recess or through-groove may be designed so as to avoid any touch with the capacitors, IC chips, resistances and the like, and may be suitably designed in consideration of a miniaturization of the connector, positional accuracy and the like.

The flexible printed circuit board 64 is formed with a substantially U-shaped slit 72 about each of the electric contact elements 68. Upon contacting a contact of a mating connector, the U-shaped slit 72 serves to cause the electric contact element 68 of the connector 60 to slidably move with the aid of the elasticity of the elastomer 66. The reason of the sliding movement is already described. The size of the slits 72 may be suitably designed in consideration of such a function and the miniaturization of the connector 60. The electric contact element 68 is connected through its conductive portion to the through-hole 76 which is in turn connected to the fine conductor 62 as shown in FIGS. 5 and 6. The size of the through-holes 76 may be suitably designed so as to receive the fine conductors 62 and enable the connection by soldering or the like and in consideration of the miniaturization of the connector 60, strength of the fine conductors 62 and capability of connection.

The fine conductors 62 will then be explained. The fine conductor 62 is substantially cylindrical and a stepped shape having a thin diameter at both ends and a thick diameter at its center. The fine conductor 62 is made of a metal by cutting a rod of a metal superior in conductivity, for example, brass into a predetermined length and machining the both end portions to a smaller diameter. The both end portions are to be inserted in the through-holes 76 and therefore the diameter of the both end portions may be suitably designed so that the both end portions are received in the through-holes 76 and connected thereto by soldering. The center portion of the fine conductor 62 is to be embedded in the elastomers 66 and therefore the diameter of the center portion may be suitably designed in consideration of the miniaturization of the connector 60, narrowed pitches and conductivity. The respective lengths of the portions of the fine conductor may be suitably designed in consideration of the thicknesses of the flexible printed circuit boards 64 and the elastomer 66.

The elastomers 66 will then be explained. The elastomer 66 is formed with inserting holes 78 for inserting the fine conductors 62 thiereinto, respectively. The diameter of the inserting holes 78 may be suitably designed so as to permit the fine conductors 62 to be inserted into the inserting holes 78 and in consideration of holding force for the fine conductors 62 and the like. The diameter of the inserting holes 78 is approximately 20 μm smaller than the diameter of the center portions of the fine conductors 62 in the embodiment. The elastomer 66 is preferably formed with a recess 82 at each of ends of the inserting holes 78 for preventing warp of the elastomer 66 caused by part of the elastomer unexpectedly extending on a shoulder 80 of the fine conductor 62. The elastomers 66 are formed from silicon rubber or fluororubber.

Moreover, a connector 110 using the electric contacts explained by referring to FIGS. 11 and 13 will then be explained. The connector 110 mainly comprises flexible printed circuit boards 114, electric contacts 120, fine conductors 112 and an elastomer 116 as shown in FIG. 13.

The flexible printed circuit board 114 will then be explained. The flexible printed circuit board 114 includes a polyimide layer 115 and on both sides of it copper foils 140 embracing the polyimide layer 115. In order to provide electric contacts 120 at locations corresponding to mating contacts, the board 114 is processed by an etching process or machined by the laser machining from the side of one surface so as to form blind holes 127 to expose the copper foil 140 on the other side, and the same time the board 114 is formed with a plurality of through-holes 126. Thereafter, the copper foils 140 on both the sides, insides of the blind holes 127 and the through-holes 126 are plated with copper to form copper plate layers 150, thereby achieving continuity across both the copper foils 140 through the blind hole 122 and the through-hole 122. Subsequently, the metal balls 144 are arranged and the protrusion contacts 145 are formed as described above in a manner to adapt to shape of the mating contacts so as to optimize the shape of the electric contacts. The sizes of the metal balls 144 and the protrusion contacts 145 may be suitably designed in consideration of connection stability, miniaturization of the electrical connector 110, pitches of the electric contacts 120 and the like.

The flexible printed circuit board 114 is formed with U-shaped slits 122 about the electric contacts 120. Upon contacting a contact of a mating connector, the U-shaped slit 122 serves to cause the electric contact 120 of the connector 110 to slidably move with the aid of the elasticity of the elastomer 116. The reason of the sliding movement is already described. The size of the slits 122 may be suitably designed in consideration of such a function and the miniaturization of the connector 110. The electric contact 120 is connected through a copper plating layer 150 to the through-hole 126 as shown in FIG. 11, the through-hole 126 being connected to the fine conductor 112. The size of the through-holes 126 may be suitably designed so as to receive the fine conductors 112 and enable the connection by soldering or the like and in consideration of the miniaturization of the connector 110, strength of the fine conductors 112 and their capability of connection.

The fine conductors 112 will then be explained. The fine conductor 112 is substantially cylindrical and a stepped shape having a thin diameter at both ends and a thick diameter at its center. The fine conductor 112 is made of a metal by cutting a rod of a metal superior in conductivity, for example, brass into a predetermined length and machining the both end portions to a smaller diameter. The both end portions are to be inserted in the through-holes 126 and therefore the diameter of the both end portions may be suitably designed so that the both end portions are received in the through-holes 126 and connected thereto by soldering. The center portion of the fine conductor 112 is to be embedded in the elastomer 116 and therefore the diameter of the center portion may be suitably designed in consideration of the miniaturization of the connector 110, narrowed pitches and conductivity. The respective lengths of the portions of the fine conductor may be suitably designed in consideration of the thicknesses of the flexible printed circuit boards 114 and the elastomer 116.

The elastomer 116 will then be explained. The elastomer 116 is formed with inserting holes 128 for inserting the fine conductors 112 thiereinto, respectively. The diameter of the inserting holes 128 may be suitably designed so as to permit the fine conductors 112 to be inserted into the inserting holes 128 and in consideration of holding force for the fine conductors 112 and the like. The diameter of the inserting holes 128 is approximately 0.02 mm smaller than the diameter of the center portions of the fine conductors 112 in the embodiment.

Further, an electrical connector 210 using the electric contacts 220 described by referring to FIGS. 15A to 17C will be explained with reference to FIG. 18. The electrical connector 210 comprises at least an elastomer (elastic body) 216, fine conductors 212 and flexible printed circuit boards 214.

First, the flexible printed circuit board 214 will be explained. The circuit board 214 includes a polyimide layer 215 and on both sides of it copper foils 240 embracing the polyimide layer 215 and is formed with electric contacts 220 having a shape adapted to mating contact and located corresponding to the mating contacts. The shape of the electric contacts 220 is spherical using a metal ball 244 in the embodiment, and the electric contact is formed by the method disclosed in the Patent Literature 2 or other method. Of course, the electric contact 220 is partly coated with a conductive hard film 221 at least over the area to contact a mating contact.

The flexible printed circuit board 214 is formed with U-shaped slits 222 about the electric contacts 220. Upon contacting a contact of a mating connector, the U-shaped slit 222 serves to cause the electric contact 220 of the connector 210 to slidably move with the aid of the elasticity of the elastomer 216. The reason of the sliding movement is already described. The size of the slits 222 may be suitably designed in consideration of such a function and the miniaturization of the connector 210. The electric contact 220 is connected through a copper plating layer 250 to the through-hole 226 as shown in FIG. 18, the through-hole 226 being connected to the fine conductor 212. The size of the through-holes 226 may be suitably designed so as to receive the fine conductors 212 and enable the connection by soldering or the like and in consideration of the miniaturization of the connector 210, strength of the fine conductors 212 and their capability of connection.

The fine conductors 212 will then be explained. The fine conductor 212 is substantially cylindrical and a stepped shape having a thin diameter at both ends and a thick diameter at its center. The fine conductor 212 is made of a metal by cutting a rod of a metal superior in conductivity, for example, brass into a predetermined length and machining the both end portions to a smaller diameter. The both end portions are to be inserted in the through-hole 226 and therefore the diameter of the both end portions may be suitably designed so that the both end portions are received in the through-holes 226 and connected thereto by soldering. The center portion of the fine conductor 212 is to be embedded in the elastomer 216 and therefore the diameter of the center portion may be suitably designed in consideration of the miniaturization of the connector 210, narrowed pitches and conductivity. The respective lengths of the portions of the fine conductor may be suitably designed in consideration of the thicknesses of the flexible printed circuit boards 214 and the elastomer 216.

The elastomer 216 will then be explained. The elastomer 216 is formed with inserting holes 228 for inserting the fine conductors 212 thiereinto, respectively. The diameter of the inserting holes 228 may be suitably designed so as to permit the fine conductors 212 to be inserted into the inserting holes 228 and in consideration of holding force for the fine conductors 212 and the like. The diameter of the inserting holes 228 is approximately 0.02 mm smaller than the diameter of the center portions of the fine conductors 212 in the embodiment.

Finally, an electrical connector 410 using flexible printed circuit boards 414 having the U-shaped slits 446 formed by the laser beam machining method explained by referring to FIGS. 26A to 28B will be explained with reference to FIGS. 29A and 29B. The electrical connector 410 comprises at least an elastomer 416, fine conductors 412, and flexible printed circuit boards 414.

First, the flexible printed circuit board 414 will be explained. The flexible printed circuit board 414 includes a polyimide layer 415 and on both sides of it copper foils 440 embracing the polyimide layer 415. Formed on the copper foil 440 are electric contacts 444 each in the form adapted to a mating contact and at location corresponding to the mating contact. In the embodiment, the electric contacts 444 are is spherical and formed by the method disclosed in the Patent Literature 2 or other method.

The circuit board 414 is formed with substantially U-shaped slits 446 about the electric contacts 444. Upon contacting a contact of a mating connector, the U-shaped slit 446 serves to cause the electric contact 444 of the connector 410 to slidably move with the aid of the elasticity of the elastomer 416. The reason of the sliding movement is already described. The size of the slits 446 may be suitably designed in consideration of such a function and the miniaturization of the connector 410. The electric contact 444 is connected through a copper plate layer to the through-hole 422, the through-hole 422 being connected to the fine conductor 412. The size of the through-holes 422 may be suitably designed so as to receive the fine conductors 412 and enable the connection by soldering or the like and in consideration of the miniaturization of the connector 410, strength of the fine conductors 412 and their capability of connection.

The fine conductors 412 will then be explained. The fine conductor 412 is substantially cylindrical and a stepped shape having a thin diameter at both ends and a thick diameter at its center. The fine conductor 412 is made of a metal by cutting a rod of a metal superior in conductivity, for example, brass into a predetermined length and machining the both end portions to a smaller diameter. The both end portions are to be inserted in the through-hole 422 and therefore the diameter of the both end portions may be suitably designed so that the both end portions are received in the through-holes 422 and connected thereto by soldering. The center portion of the fine conductor 412 is to be embedded in the elastomer 416 and therefore the diameter of the center portion may be suitably designed in consideration of the miniaturization of the connector 410, narrowed pitches and conductivity. The respective lengths of the portions of the fine conductor may be suitably designed in consideration of the thicknesses of the flexible printed circuit boards 414 and the elastomer 416.

The elastomer 416 will then be explained. The elastomer 416 is formed with inserting holes 428 for inserting the fine conductors 412 thiereinto, respectively. The diameter of the inserting holes 428 may be suitably designed so as to permit the fine conductors 412 to be inserted into the inserting holes 428 and in consideration of holding force for the fine conductors 412 and the like. The diameter of the inserting holes 428 is approximately 0.02 mm smaller than the diameter of the center portions of the fine conductors 412 in the embodiment.

Examples of applications of the present invention are electrical connectors to be fitted between a circuit board and electronic components and more particularly the method for working a board from one direction to form a plurality of through-holes simultaneously, and an electric contacts and a method producing the electric contacts extending from a copper foil whose heights are uniform and as high as possible without increasing their diameters, and more particularly electrical connectors using such electric contacts.

Moreover, examples of applications of the present invention are electric contacts having shapes adapted to mating objects and causing continuity across copper foils on both sides of a circuit board, and particularly electric contacts having a conductive hard film superior in conductivity and wear-resistance, and more particularly electrical connectors using such electric contacts.

Furthermore, examples of applications of the present invention are structures for vertically holding pin-shaped conductors, and laser beam machining methods capable of machining a circuit board to form U-shaped slits having a width W smaller than a focused laser beam diameter D and a length L larger than the focused laser beam diameter D, and particularly electrical connectors using such a structure for vertically holding conductors or using the circuit board having slits formed by such a laser beam machining method.

While the invention has been particularly shown and described with reference to the preferred embodiments thereof, it will be understood by those skilled in the art that the foregoing and other changes in form and details can be made therein without departing from the spirit and scope of the invention.

1-31. (canceled)

32. An electric contact structure comprising:
a flexible circuit board including a polyimide layer having upper and lower surfaces and copper foils arranged on said upper and lower surfaces of to sandwich said polyimide layer;
an electric contact having a surface, at least a portion of said surface being adapted to contact a mating object, said portion being plated with a noble metal; said contact extending from a top surface of one of said copper foils, said contact secured to said top surface by solidification of a metal paste layer or conductive paste layer coated on said copper foil, said noble metal layer extending over at least a part adapted to contact a mating object;
wherein said contact is a metal ball with a spherical shape adapted to contact the mating object; and
wherein said circuit board has a substantially U-shaped slit is formed almost all around said contact so as to give flexibility of the contact when contacting with the mating object.

32. The electric contact structure of claim 31, further comprising an elastomer arranged under said circuit board.

33. The electric contact structure of claim 31, wherein said metal ball is made of an alloy.

34. The electric contact structure of claim 31, wherein said polyimide layer is provided with through holes so that said copper foils contact one another.

35. The electric contact structure of claim 34, wherein said metal ball is fixed to said copper foils by solidification of a metal paste layer or conductive paste layer coated on the upper copper foil.
